(19) United States
(12) Patent Application Publication
(10) Pub. No.: US 2008/0191203 A1
(43) Pub. Date: Aug. 14, 2008

(54) Method for Producing Gan Film, Semiconductor Device, Method for Generating Thin Film of Nitride of Group III Element and Semiconductor Device Having Thin Film of Nitride of Group III Element

(75) Inventors: Hiroshi Fujioka, Tokyo (JP); Atsushi Kobayashi, Saitama (JP)

Correspondence Address: BELL, BOYD & LLOYD, LLP, P.O. Box 1135, CHICAGO, IL, 60690, US

(73) Assignee: KANAGAWA ACADEMY OF SCIENCE AND TECHNOLOGY, Kanagawa (JP)

(21) Appl. No.: 11/815,181

(22) PCT Filed: Jan. 31, 2006
(86) PCT No.: PCT/JP2006/301938

§ 371 Date: Sep. 6, 2007

(30) Foreign Application Priority Data
Jan. 31, 2005 (JP) P2005-024034
Sep. 6, 2005 (JP) P2005-258571

(51) Int. Cl. H01L 29/267; H01L 21/205

(52) U.S. Cl. 257/43; 438/478; 257/190; 257/E21.112; 257/E29.081

(57) ABSTRACT

A GaN layer (12) is formed on a planarized surface of a ZnO substrate (11) to provide a nitride semiconductor device (10) having the GaN layer. The GaN layer (12) is formed by a first film-forming step of allowing epitaxial growth of GaN at a temperature not higher than 300° C., and a second film-forming step of allowing epitaxial growth of GaN at a temperature not lower than 550° C. on a film of GaN formed by the first film-forming step.

### TECHNICAL FIELD

This invention relates to a method for producing a GaN film, a semiconductor device having a GaN film, a method for generating a thin film of a nitride of a group III element, and a semiconductor device having a thin film of a nitride of a group III element.

The present application claims priority rights based on JP Patent Application No. 2005-24034, filed in Japan on Jan. 31, 2005, and on JP Patent Application 2005-258571, filed in Japan on Sep. 6, 2005. These JP Patent Applications of the earlier filing dates are to be incorporated by reference herein.

### BACKGROUND ART

GaN, as one of semiconductors of nitrides of the group III elements, is finding application for a blue LED (light Emitting Diode) and a blue laser diode.

GaN is generated on epitaxial growth on sapphire (Al₂O₃) or silicon carbide (SiC) mainly in accordance with a MOCVD (Organo Metallic Chemical Vapor Deposition) method.

However, GaN exhibits lattice mismatch with respect to sapphire and silicon carbide. For example, there is 23% in-plane lattice mismatch between GaN and sapphire, whereas there is 3.5% in-plane lattice mismatch between GaN and silicon carbide. Hence, many mis-fit dislocations are produced during epitaxial growth under the strain applied to the GaN crystal lattice, resulting in threading dislocations traversing the GaN layer. As a result, high-quality crystals cannot be produced, thus deteriorating the product quality.

It has also been known that ZnO may theoretically be used as a substrate for epitaxial growth of GaN.

ZnO exhibits in-plane lattice mismatch as small as 2.2%, while exhibiting lattice mismatch to the C-axis direction as small as 0.5%. Hence, it is possible with ZnO to reduce lattice mismatch more efficaciously than with sapphire or silicon carbide.

However, in actuality, ZnO has not been used as a substrate for epitaxial growth of GaN, because of the following problems (1) and (2):

(1) Zn has a high vapor pressure such that it is difficult to planarize the surface of a Zn substrate; and
(2) Since GaN reacts readily with ZnO, a compound layer is formed on the surface of ZnO, with the result that a merit of the lattice-matched substrate cannot be exploited.

The present inventor has proposed an invention for solving this problem in an International Patent Application (PCT/1B2004/000916). Specifically, the problem (1) may be solved by processing by heating as a Zn substrate is encircled by a plate of ZnO, while the problem (2) may be solved by using a low temperature as a temperature for epitaxial growth of GaN.

However, when GaN is allowed to grow by epitaxy at a lower temperature, the resulting crystal suffers from many point defects and exhibits poor crystalline performance.

Further, in allowing crystalline growth of the nitride of the group III element, not on the ZnO substrate, as described above, but on other lattice-matched substrates, exhibiting only small lattice mismatch, high-quality thin films cannot be produced in stability, with the result that the merit of the lattice matched substrate again cannot be exploited. For example, if GaN is allowed to grow at a growth temperature not lower than 700° C. on a 6H—SiC substrate or the like, in accordance with MOCVD or MBE (Molecular Beam Epitaxy), as conventionally, 3D growth occurs as from the initial growth stage. On the other hand, an Hf substrate has high electrical conductivity and lattice mismatch as low as 0.3%, and hence is attracting attention as a substrate for growth of GaN. However, if the above reaction method is used, Hf reacts vigorously with the nitride of the group III element to render it difficult to produce a high-quality nitride of the group III element (see Non-Patent publication 3, for instance). The same may be said of the substrates of LiGaO₂, (Mn, Zn) Fe₂O₄, MgAl₂O₄, LiAlO₂ and NdGaO₃ (see W. A. Doolittle et al., Solid-State Electronics 44 (2000) 229-238, for instance).

### DISCLOSURE OF THE INVENTION

It is an object of the present invention to solve the above problems and to provide a method for generating a GaN film whereby GaN with high crystalline performance may be allowed to grow by epitaxy on a ZnO substrate, and a semiconductor device on a Zn substrate of which has been formed a GaN film of high crystalline performance.

It is another object of the present invention to provide a method for generating a thin film of a nitride of the group III element whereby a nitride of the group III element with high crystalline performance may be allowed to grow on the lattice-matched substrate, and a semiconductor device on a lattice-matched substrate of which has been formed a film of the nitride of the group III element with high crystalline performance.

A method for generating a GaN film according to the present invention comprises a first film-forming step of allowing epitaxial growth of GaN at a temperature not higher than 300° C. on a planarized surface of a ZnO substrate, and a second film-forming step of allowing epitaxial growth of GaN at a temperature not lower than 550° C. on a film of GaN formed by the first film-forming step.

In case GaN is allowed to grow by epitaxy on a surface of the ZnO substrate at a temperature not higher than 300° C., there occurs only little interfacial reaction between ZnO and GaN. In case GaN ia allowed to grow by epitaxy at a temperature not lower than 550° C., it is possible to suppress generation of point defects.

A method for generating a GaN film according to the present invention comprises a first film-forming step of allowing epitaxial growth of InGaN on a planarized surface of a ZnO substrate, a second film-forming step of allowing epitaxial growth of GaN at a temperature not higher than 320° C. on a film of InGaN formed by the first film-forming step, and a third film-forming step of allowing epitaxial growth of GaN at a temperature not lower than 550° C. on a film of GaN formed by the second film-forming step.

In case GaN is allowed to grow by epitaxy on InGaN at a temperature not higher than 320° C., InGaN is not destructed by heat, thus prohibiting the film from being lowered in quality.

A semiconductor device according to the present invention includes a ZnO substrate, having a planarized surface, and a GaN film, formed on the ZnO substrate. The GaN film has been formed by a first film-forming step of allowing epitaxial growth of GaN at a temperature not higher than 300° C., and a second film-forming step of allowing epitaxial growth of GaN at a temperature not lower than 550° C. on a film of GaN formed by the first film-forming step.

In case GaN is allowed to grow by epitaxy on a surface of the ZnO substrate at a temperature not higher than 300° C., there occurs only little interfacial reaction between ZnO and GaN. In case GaN ia allowed to grow by epitaxy at a temperature not lower than 550° C., it is possible to suppress generation of point defects.

A semiconductor device according to the present invention includes a ZnO substrate, having a planarized surface, an InGaN layer formed on a surface of the ZnO substrate, and a GaN film, formed on the InGaN layer. The InGaN film has been formed by a first film-forming step of allowing epitaxial growth of InGaN on a planarized surface of a ZnO substrate. The aforementioned GaN film has been formed by a second film-forming step of allowing epitaxial growth of GaN at a temperature not higher than 320° C. on a film of InGaN formed by the first film-forming step, and by a third film-forming step of allowing epitaxial growth of GaN at a temperature not lower than 550° C. on a film of GaN formed by the second film-forming step.

In case GaN is allowed to grow by epitaxy on InGaN at a temperature not higher than 320° C., InGaN is not destructed by heat, thus prohibiting the film from being lowered in quality.

A GaN crystal according to the present invention comprises a first GaN layer generated by epitaxial growth at a temperature not higher than 300° C., and a second GaN layer formed on the first GaN layer by epitaxial growth at a temperature not lower than 550° C.

An InGaN/GaN crystal according to the present invention comprises an InGaN layer generated by epitaxial growth, a first GaN layer generated by epitaxial growth at a temperature not higher than 320° C., and a second GaN layer formed on the first GaN layer by epitaxial growth at a temperature not lower than 550° C.

A method for generating a thin film of a nitride of a group III element according to the present invention comprises a first film-forming step of allowing epitaxial growth of a nitride of a group III element at a temperature not higher than 300° C. on a planarized surface of a substrate lattice-matched to the nitride of the group III element, and a second film-forming step of allowing epitaxial growth of the nitride of the group III element at a temperature not lower than 550° C. on the nitride of the group III element formed by the first film-forming step.

A semiconductor device according to the present invention comprises a substrate with a planarized surface, lattice-matched to a nitride of the group III element, and a film of the nitride of the group III element, formed on the lattice-matched substrate. The film of the nitride of the group III element has been formed by a first film-forming step of allowing epitaxial growth of a nitride of a group III element at a temperature not higher than 300° C., and a second film-forming step of allowing epitaxial growth of the nitride of the group III element at a temperature not lower than 550° C. on a film of the aforementioned nitride of the group III element formed by the aforementioned first film-forming step.

A crystal of a group III element according the present invention comprises a first layer of a nitride of a group III element, generated by epitaxial growth at a temperature not higher than 300° C., and a second layer of a nitride of a group III element, formed on the first layer of the nitride of the group III element by epitaxial growth at a temperature not lower than 550° C.

By allowing the epitaxial growth of the first layer of the nitride the group III element in the first film-forming step at a temperature not higher than the above specified temperature, and allowing the epitaxial growth of the second layer of the nitride of the group III element in the second film-forming step at a temperature not lower than the above specified temperature, the first layer of the nitride of the group III element transmits the crystalline information of high quality and high integrity of the lattice-matched substrate to the second the nitride layer of the group III element, in the second film-forming step, thus suppressing point defects from being produced at the time of growth of the second layer of the nitride of the group III element. Further, since the nitride layer of the group III element is grown in the second film-forming step at a temperature not lower than the above specified temperature, the fine grains present at the time of growth of the first nitride layer of the group III element become fused together and extinct.

With the method for generating the GaN film, according to the present invention, the GaN film may be formed on ZnO, while the GaN film, thus formed, may be of high quality.

Further, with the semiconductor device, GaN crystal and the InGaN/GaN crystal, according to the present invention, GaN is formed on the ZnO substrate, with the GaN film being of high quality.

Additionally, with the method for forming a GaN film, according to the present invention, since the GaN film is formed on ZnO, and the ZnO substrate is a conductor, ZnO may be used as a lower electrode of the semiconductor device.

Moreover, with the method for forming a thin film of the nitride of the group III element, in which a nitride of the group III element is allowed to grow by epitaxy, at a temperature not higher than 300° C., on the planarized surface of the substrate, lattice-matched to the nitride of the group III element, and in which a nitride of the group III element is further allowed to grow by epitaxy, at a temperature not lower than 550° C., on the nitride of the group III element, already formed, it is possible to suppress the interfacial reaction and to generate a thin film of the nitride of the group III element to high crystalline performance.

Other objects and advantages derived from the present invention will become more apparent from the following description which will now be made in conjunction with the accompanying drawings.

### BRIEF DESCRIPTION OF THE DRAWINGS

FIG. 1 is a schematic cross-sectional view of a nitride semiconductor device according to a first embodiment.

FIG. 2 is a schematic view showing an atomic disposition of ZnO and GaN.

FIG. 3 is a flowchart showing a fabrication sequence of the nitride semiconductor device of the first embodiment.

FIG. 4 is a schematic view showing the state a Zn substrate is surrounded by sintered members of ZnO.

FIGS. 5A and 5B show the 0001 plane of the ZnO substrate, as observed over an atomic force microscope,.

FIGS. 6A to 6D show the surface of GaN grown on a surface of a Zn substrate planarized by a PLD method and results observed over an atomic force microscope,.

FIG. 7 shows the height of each atomic step at an ambient temperature, as measured with an atomic force microscope.

FIGS. 8A to 8D show the surface of GaN grown on a surface of a Zn substrate planarized by a PLD method, as observed in accordance with the RHEED method.

FIGS. 9A and 9B show the results of measurement in real-time of status changes of GaN in accordance with the RHEED method in the course of vapor deposition of GaN in the low-temperature film-forming process.

FIG. 10 is a schematic view showing the configuration of a PLD apparatus.

FIG. 11 is a graph showing repetition rate characteristics of an emitted light volume in case of irradiation of the GaN film with a HeCd laser.

FIG. 12 is a schematic cross-sectional view of a nitride semiconductor device according to a second embodiment.

FIG. 13 is a flowchart for illustrating the fabrication sequence of the nitride semiconductor device of the second embodiment.

FIGS. 14A to 14C schematically show surface states of InGaN obtained on processing by heating of In GaN (In: 20%; GaN: 60%) in ultra-high vacuum.

FIGS. 15A and 15B are graphs showing the results of observation of RHEED oscillations of InGaN and GaN as deposited on a ZnO substrate in accordance with the fabrication sequence of the second embodiment.

FIG. 16 is a schematic cross-sectional view of a nitride semiconductor device according to a third embodiment.

FIG. 17 is a flowchart showing the fabrication sequence of a nitride semiconductor device according to the third embodiment.

FIG. 18 illustrates the results of observation of the (0001) plane of the 6H—SiC substrate after CMP processing.

FIGS. 19A and 19B illustrate the results of observation of the (0001) plane of the 6H—SiC substrate plane after CMP processing followed by heat treatment.

FIG. 20 shows a RHEED pattern obtained on allowing GaN to grow to a film thickness of approximately 200 nm at 700° C. on the (0001) plane of the 6H—SiC substrate obtained on processing only with CMP.

FIG. 21 shows a RHEED pattern obtained on allowing GaN to grow to a film thickness of approximately 200 nm at 300° C. on the (0001) plane of the 6H—SiC substrate obtained on processing only with CMP.

FIG. 22 shows a RHEED pattern obtained on allowing GaN to grow to a film thickness of approximately 200 nm at ambient temperature on the (0001) plane of the 6H—SiC substrate obtained on processing only with CMP.

FIG. 23 shows a RHEED pattern obtained on allowing GaN to grow at 700° C. on the (0001) plane of the 6H—SiC substrate obtained on processing with CMP followed by heat treatment.

FIG. 24 shows a RHEED pattern obtained on allowing GaN to grow at 300° C. on the (0001) plane of the 6H—SiC substrate obtained on processing with CMP followed by heat treatment.

FIG. 25 shows a RHEED pattern obtained on allowing GaN to grow at ambient temperature on the (0001) plane of the 6H—SiC substrate obtained on processing with CMP followed by heat treatment.

FIG. 26 is a graph showing an intensity profile of a RHEED specular spot for high-temperature growth at 700° C.

FIG. 27 shows a RHEED image at a film thickness of 3 ML of a GaN thin film.

FIG. 28 shows a RHEED image at a film thickness of 6 ML of a GaN thin film.

FIG. 29 is a schematic view for illustrating high-temperature growth at 700° C.

FIG. 30 is a graph showing an intensity profile of a RHEED specular spot in the course of growth at ambient temperature.

FIG. 31 shows a RHEED image when the GaN thin film is of a film thickness of 3 ML.

FIG. 32 shows a RHEED image when the GaN thin film is of a film thickness of 13 ML.

FIG. 33 is a schematic view for illustrating ambient-temperature growth.

FIGS. 34A to 34C show an AFM image of a GaN thin film grown 9 nm at ambient temperature.

FIG. 35 is a schematic cross-sectional view of a nitride semiconductor device according to a fourth embodiment.

FIG. 36 is a schematic view showing an Hf crystalline structure.

FIG. 37 is a flowchart showing the fabrication sequence of the nitride semiconductor device according to a fourth embodiment.

FIG. 38 is a graph showing results of measurement of the Hf4f spectrum.

FIG. 39 is a graph showing results of measurement of the O1s spectrum.

FIG. 40 is a graph showing results of measurement of the C1s spectrum.

FIG. 41 shows the results of observation by RHEED by heating to 1000° C.

FIG. 42 shows the results of observation by AFM by heating to 1000° C.

FIG. 43 shows a RHEED pattern at a film thickness of 0.3 nm of GaN grown at a substrate temperature of 700° C.

FIG. 44 shows a RHEED pattern at a film thickness of 3.3 nm of GaN grown at a substrate temperature of 700° C.

FIG. 45 shows a RHEED pattern at a film thickness of 6.7 nm of GaN grown at a substrate temperature of 700° C.

FIG. 46 shows a RHEED pattern at a film thickness of 10.0 nm of GaN grown at a substrate temperature of 700° C.

FIG. 47 is a graph showing measured results by XPS of a polycrystalline GaN surface on a Hf substrate.

FIG. 48 shows a RHEED pattern at a film thickness of 8 nm of GaN grown at ambient temperature.

FIG. 49 shows a RHEED pattern at a film thickness of 20 nm of GaN grown at ambient temperature.

FIG. 50 shows a RHEED pattern at a film thickness of 25 nm of GaN grown at ambient temperature.

FIG. 51 shows a RHEED pattern at a film thickness of 30 nm of GaN grown at ambient temperature.

FIG. 52 is a graph showing RHEED intensity oscillations in case GaN is allowed to grow at ambient temperature.

FIG. 53 is a graph showing measured results by XPS of GaN grown at ambient temperature.

FIG. 54 is a graph showing measured results by GIXR of GaN grown at ambient temperature.

FIG. 55 is a graph showing changes in film thickness of a GaN thin film plotted against the heat-treatment temperature.

FIG. 56 is a graph showing results of measurement by GIXR at 700° C. of a thin GaN film grown at ambient temperature.

FIG. 57 shows results observed by AFM at 700° C. of a thin GaN film grown at ambient temperature.

FIG. 58 is a schematic cross-sectional view showing a nitride semiconductor device according to a fifth embodiment.

FIG. 59 is a flowchart showing a fabrication sequence of the nitride semiconductor device according to the fifth embodiment.

FIG. 60 shows a RHEED image before heat treatment on a Metal-face.

FIG. 61 shows a RHEED image following heat treatment on the Metal-face.

FIG. 62 shows a RHEED image before heat treatment on an O-face.

FIG. 63 shows a RHEED image following heat treatment on the O-face.

FIG. 64 shows a RHEED image in case GaN has been grown at 700° C. on an O-face substrate.

FIG. 65 shows a RHEED image in case GaN has been grown at 500° C. on an O-face substrate.

FIG. 66 shows a RHEED image in case GaN has been grown at 300° C. on an O-face substrate.

FIG. 67 shows a RHEED image in case GaN has been grown at ambient temperature on an O-face substrate.

FIG. 68 shows a RHEED image in case GaN has been grown at 700° C. on a Metal-face substrate.

FIG. 69 shows a RHEED image in case GaN has been grown at 500° C. on the Metal-face substrate.

FIG. 70 shows a RHEED image in case GaN has been grown at 300° C. on the Metal-face substrate.

FIG. 71 shows a RHEED image in case GaN has been grown at ambient temperature on the Metal-face substrate.

FIG. 72 is a pole figure of the (0001) orientation.

FIG. 73 is a pole figure of the (11-24) orientation.

FIG. 74 is a graph showing RMS values of surface roughness plotted against the growth temperature.

FIG. 75 is a graph showing the thickness of an interfacial reaction layer plotted against the growth temperature.

FIG. 76 is a schematic cross-sectional view showing a nitride semiconductor device according to a sixth embodiment.

FIG. 77 is a schematic view showing a crystalline structure of a MnZn ferrite substrate.

FIG. 78 is a flowchart showing the fabrication sequence of the nitride semiconductor device according to the sixth embodiment.

FIG. 79 is a graph showing the results of in-situ RHEED observation in the course of growth of a GaN thin film at ambient temperature.

FIG. 80 shows results of measurement of the thickness of the interfacial layer by GIXR (Grazing Incidence X-Ray Reflectometry).

FIG. 81 shows a RHEED image in case GaN is allowed to grow at 700° C.

FIG. 82 shows a RHEED image in case GaN is allowed to grow at ambient temperature.

FIG. 83 shows a RHEED image in case GaN is allowed to grow at ambient temperature and subsequently at 700° C.

FIGS. 84A and 84B are graphs showing XRD curves of a GaN film grown at ambient temperature and having a film thickness of 100 nm.

FIG. 85 is a schematic cross-sectional view showing a nitride semiconductor device according to a seventh embodiment.

FIG. 86 is a flowchart showing the fabrication sequence of the nitride semiconductor device according to the seventh embodiment.

FIG. 87 is a graph showing the results of measurement of the thickness of an interfacial layer plotted against the growth temperature by GIXR (Grazing Incidence X-Ray Reflectometry).

FIGS. 88A and 88B show a RHEED image and the results of measurement of XRD in case InN is allowed to grow by epitaxy at ambient temperature, respectively.

FIGS. 89A and 89B show a RHEED image and the results of measurement of XRD in case InN is allowed to grow by epitaxy at 150° C., respectively.

FIGS. 90A and 90B show a RHEED image and the results of measurement of XRD in case InN is allowed to grow by epitaxy at 400° C., respectively.

FIGS. 91A and 91B show a RHEED image and the results of measurement of XRD in case InN is grown by epitaxy at 550° C., respectively.

FIG. 92 shows the results of observation by an atomic force microscope in case InN has been grown at ambient temperature.

FIG. 93 shows the results of observation by an atomic force microscope in case InN has been grown at 150° C.

FIG. 94 shows the results of observation by an atomic force microscope in case InN has been grown at 400° C.

FIG. 95 shows the results of observation by an atomic force microscope in case InN has been grown at 550° C.

FIG. 96 shows the results of measurement of XRD of InN at 400° C. and at ambient temperature.

FIG. 97(A) shows a RHEED image in case an InN layer has been allowed to grow at 500˜550° C., FIG. 97(B) shows a RHEED image in case an InN layer has been allowed to grow at ambient temperature, and FIG. 97(C) shows a RHEED image in case an InN layer has been allowed to grow at ambient temperature and subsequently at 500˜550° C.

FIG. 98 is a graph showing the results of observation of GIXR of the InN layer.

FIG. 99 is a graph showing the thicknesses of the interfacial reaction layers against the growth temperature in case GaN, InN and AlN are grown on MnZn ferrite substrates.

FIG. 100 shows a RHEED image of AlN grown at 750° C.

FIG. 101 shows a RHEED image of AlN grown at 550° C.

FIG. 102 shows a RHEED image of AlN grown at ambient temperature.

FIG. 103 shows the results of observation of AlN grown at 750° C.

FIG. 104 shows the results of observation of AlN grown at 550° C.

FIG. 105 shows the results of observation of AlN grown at ambient temperature.

FIG. 106 is a graph showing an XRD curve of AlN grown at ambient temperature.

FIG. 107 is a graph showing an XRD curve of AlN grown at ambient temperature.

FIGS. 108A to 108C show the results of observation of the initial growth of AlN.

FIG. 109 is a schematic cross-sectional view of a nitride semiconductor device of an eighth embodiment.

FIG. 110 shows lattice mismatch as a function of content proportions of Al and Ga.

FIG. 111 is a flowchart showing the fabrication sequence of the nitride semiconductor device of the eighth embodiment.

FIG. 112 shows a RHEED image of AlGaN grown at 600° C.

FIG. 113 shows a RHEED image of AlGaN grown at 400° C.

FIG. 114 shows a RHEED image of AlGaN grown at 200° C.

FIG. 115 shows a RHEED image of AlGaN grown at ambient temperature.

FIG. 116 shows an AFM image of AlGaN grown at 600° C.

FIG. 117 shows an AFM image of AlGaN grown at 400° C.

FIG. 118 shows an AFM image of AlGaN grown at 200° C.

FIG. 119 shows an AFM image of AlGaN grown at ambient temperature.

FIG. 120 is a graph showing the results of measurement of EBSD against the growth temperature of AlGaN grown to a film thickness of approximately 30 nm.

FIG. 121 is a graph showing RHEED intensity oscillations of growth of AlGaN at ambient temperature.

FIG. 122 shows an AFM image of ZnO after heat treatment.

FIG. 123 shows an AFM image of AlGaN grown at ambient temperature.

FIG. 124 is a graph showing RHEED intensity oscillations at KrF excimer laser repetition rates of 10 Hz, 20 Hz, 30 Hz and 40 Hz in the course of growth at ambient temperature.

FIG. 125 is a graph showing the growth rate against the KrF excimer laser repetition rates in the course of growth at ambient temperature.

FIG. 126 shows a RHEED image in case the KrF excimer laser is of 10 Hz in the growth at ambient temperature.

FIG. 127 shows a RHEED image in case the KrF excimer laser is of 20 Hz in the growth at ambient temperature.

FIG. 128 shows a RHEED image in case the KrF excimer laser is of 30 Hz in the growth at ambient temperature.

FIG. 129 shows a RHEED image in case the KrF excimer laser is of 40 Hz in the growth at ambient temperature.

FIG. 130 is a graph showing the results of measurement of EBSD against the growth rate of AlGaN grown to a film thickness of approximately 30 nm.

FIG. 131 shows an AFM image in case AlGaN grown at ambient temperature is heat-treated at ambient temperature.

FIG. 132 shows an AFM image in case AlGaN grown at ambient temperature is heat-treated at 300° C.

FIG. 133 shows an AFM image in case AlGaN grown at ambient temperature is heat-treated at 700° C.

### BEST MODE FOR CARRYING OUT THE INVENTION

The best mode for carrying out the present invention is now described in detail with reference to the drawings.

Preferred embodiments of the present invention are now described in detail with reference to the drawings. The present invention is applied to a semiconductor device having a GaN film and a process for fabricating the same. The present invention is also applied to a semiconductor device employing a lattice matched substrate, viz. a lattice exhibiting only little lattice mismatch, and a fabrication process for the semiconductor device.

In the present specification, the lattice mismatch is represented by {(lattice constant of a lattice crystal)-(lattice constant of a substrate crystal)}/(lattice constant of a substrate crystal), where the lattice constant denotes the period of repetition of unit crystals. The lattice-matched substrate means a substrate exhibiting little lattice mismatch with respect to a film crystal, and specifically means a substrate with the lattice mismatch equal to or less than 16%.

### First Embodiment

Initially, a process for fabrication of a semiconductor according to a first embodiment is described.

### (Constitution of a Semiconductor)

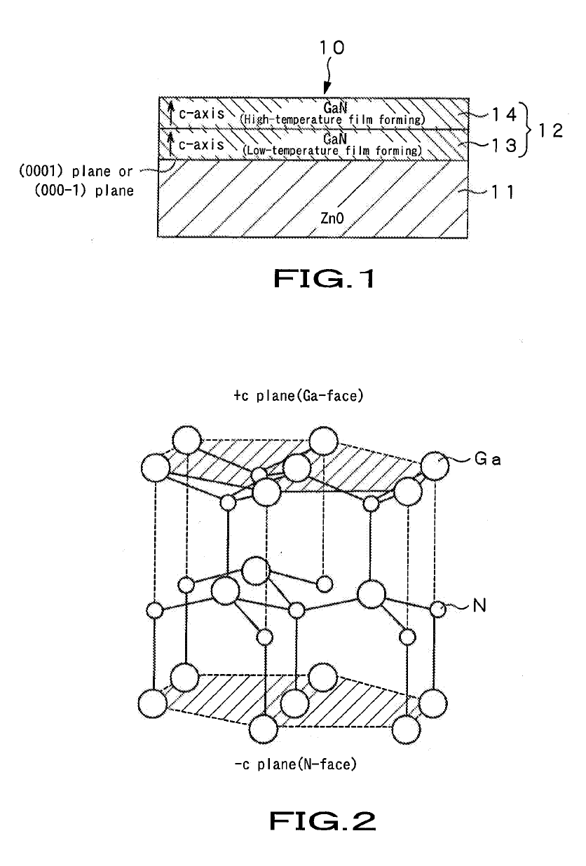

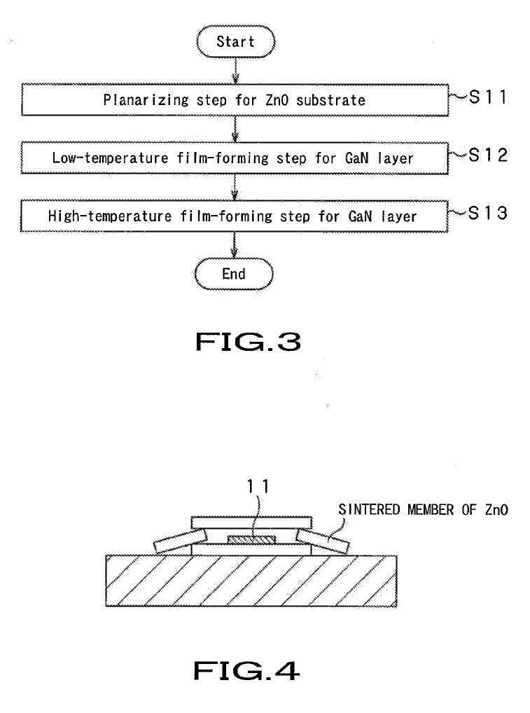

In a semiconductor device fabrication process of a first embodiment, a nitride semiconductor device 10, including a ZnO substrate 11 and a GaN layer 12 formed thereon, as shown in FIG. 1, is fabricated.

The nitride semiconductor device 10 includes the GaN layer 12 oriented so that the c-axis of GaN, which is a hexagonal crystal, is perpendicular to the (0001) plane or the (000-1) plane of the ZnO substrate 11, which is formed of ZnO. Also, this GaN layer 12 is made up of a first GaN layer 13 and a second GaN layer 14. The first GaN layer 13 is formed by epitaxial growth on the ZnO substrate 11 at a low temperature of not higher than 300° C., whereas the second GaN layer 14 is formed by epitaxial growth on the first GaN layer 13 at a high temperature of not lower than 550° C.

ZnO that makes up the ZnO substrate 11 has a crystalline structure of the wurtzite type, with the lattice constant a being such that a=3.252 Å, with the forbidden bandwidth of 3.4 eV and with the binding energy of excitons being 21 meV.

GaN that makes up the GaN layer 12 deposited on the ZnO substrate 11 also has a crystalline structure of the wurtzite type (see FIG. 2), with the lattice constant a being such that a=3.189 Å, with the forbidden bandwidth of 3.4 eV and with the binding energy of excitons being 21 meV.

Since the lattice constants of ZnO and GaN, having the above-described crystalline structures, are approximately equal to each other, it is possible to reduce lattice mismatch to as small a value as possible.

### (Overall Flow)

The respective process steps for fabricating the nitride semiconductor device 10 are now described.

In fabricating the nitride semiconductor device 10, the planarizing step (S11) for the ZnO substrate, the low-temperature film-forming step (S12) for the GaN layer and the high-temperature film-forming step (S13) for the GaN layer are carried out in this sequence.

### (Planarizing Step S11)

In the planarizing step S11, the ZnO substrate 11 is initially sliced so that the substrate surface will become a (0001) plane or a (000-1) plane.

In the planarizing step S11, the (0001) plane or the (000-1) plane of the ZnO substrate 11, thus sliced, is mechanically polished using, for example, a diamond slurry. In this mechanical polishing, the particle size of the diamond slurry used is progressively comminuted and, finally, the diamond slurry of the particle size of 0.5 μm is used to realize mirror polishing. At this time, polishing for planarization may further be continued, with the use of colloidal silica, up to the RMS value of the surface roughness of 10 Å.

In the planarizing step S11, the ZnO substrate 11, thus mechanically polished, is encircled by a box-shaped ZnO sintered member, as shown in FIG. 4, in a high temperature oven, controlled to a temperature not lower than 800° C. In this state, the ZnO substrate is processed by heating. It is sufficient for the ZnO substrate 11 to be encircled by the ZnO sintered member, while it is not indispensable to have the ZnO substrate 11 encircled in its entirety by the sintered member. It is also possible to prepare a crucible or an enclosure from a ZnO sintered member and to place the ZnO substrate 11 in the so prepared crucible or enclosure.

Since the vapor pressure of Zn is rather high, there is presented a problem that the ZnO substrate 11, used as a substrate material, may be decomposed on processing by heating. By heating the ZnO substrate 11, encircled by the ZnO sintered member, as shown in FIG. 4, the ZnO substrate may be processed by heating as the vapor pressure of ZnO is exerted, thus enabling suppression of decomposition of the ZnO substrate 11 itself.

The following may account for this suppression of decomposition. Since the vapor pressure of Zn is rather high, Zn is efficiently removed from the ZnO substrate 11, based on the reaction: 2ZnO=2Zn+O₂, except if the ZnO substrate is encircled by the ZnO sintered member. If the ZnO substrate 11 is encircled by the ZnO sintered member, Zn escapes from the ZnO sintered member into a gaseous phase around the ZnO substrate, resulting in increased Zn concentration in the gaseous phase. Hence, it becomes possible to lower the fugacity of Zn in the ZnO substrate 11, viz. the ability of the Zn in the ZnO substrate 11 escaping into the gaseous phase, and hence to suppress decomposition of the ZnO substrate 11 itself.

Meanwhile, to suppress Zn in the ZnO substrate 11 from escaping into the gaseous phase, the ZnO substrate 11 may be encircled with a Zn containing material, in lieu of with the ZnO sintered member. Examples of the Zn-containing material include a ZnO single crystal or a plate of Zn. It is possible in these cases to suppress decomposition of the ZnO substrate 11 itself.

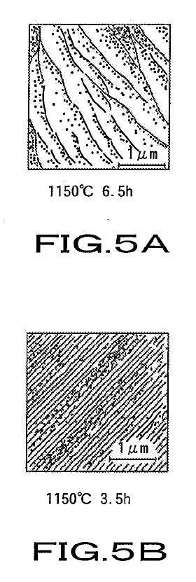

FIG. 5A shows the results of observation with an atomic force microscope of a (0001) plane of the ZnO substrate 11 processed by heating at 1150° C. for 6.5 hours. It is seen from FIG. 5A that curvilinear atomic steps have been formed on the (0001) plane of the ZnO substrate 11. FIG. 5B shows the results of observation with an atomic force microscope of the (000-1) plane of the ZnO substrate 11 processed by heating at 1150° C. for 3.5 hours. It is seen from FIG. 5B that smooth linear atomic steps have been formed in a regular order on the (0001) plane of the ZnO substrate 11. Meanwhile, the heights of the atomic steps, as measured with the atomic force microscope, were approximately 0.5 nm.

By processing the ZnO substrate 11, based on the above conditions, it becomes possible to use the ZnO substrate 11, carrying the atomic steps thereon, as a substrate for growth of a crystal. The fact that these atomic steps may be noticed indicates that the substrate surface can be finished to the most planar state possible such that a satisfactory GaN thin film can be formed thereon. Additionally, since these atomic steps may serve as nuclei for epitaxial growth of GaN, it is possible to establish an optimum film-forming environment.

Moreover, since the ZnO substrate 11 is a conductor, the ZnO substrate itself may be used as an electrode. That is, unlike the case of using an insulating substrate, such as sapphire electrode, a semiconductor the part of which lying below the GaN layer is an electrode may be produced, thus simplifying the fabrication process.

### (Low Temperature Film Forming Step S12)

In the next following low-temperature film-forming step S12, a first GaN layer 13 is grown by epitaxy by a pulse laser deposition method, referred to below as PLD method, on a surface of a ZnO substrate 11, planarized by the step S11.

The temperature during the growth of GaN is set to 300° C. or lower. The initial GaN growth rate is set to 10 nm/hour.

The temperature during the growth of GaN of 300° C. or lower is selected because no interfacial reaction may take place for this temperature range on a ZnO—GaN interface, such that no interface reaction layer is generated.

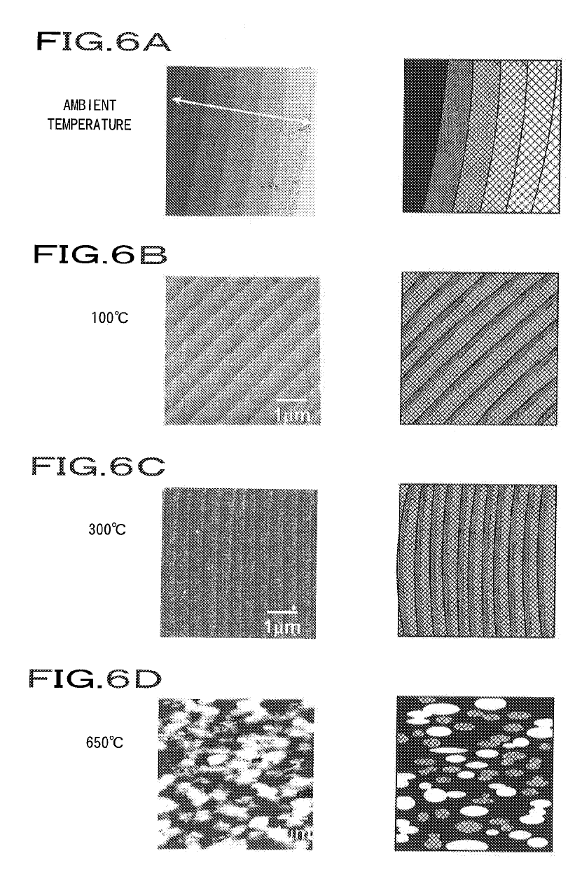

FIG. 6 shows the results of observation by the atomic force microscope of the GaN surface after GaN has been grown on the plane of the ZnO substrate 11 by the PLD method. Meanwhile, the left and right sides of FIG. 6 depict a view derived from a photo and a schematic view thereof, respectively.

FIG. 6A shows the results of observation of the surface when the growth temperature is the ambient temperature, and FIG. 6B shows the results of observation of the surface when the growth temperature is 100° C. FIG. 6C shows the results of observation of the surface when the growth temperature is 300° C., whereas FIG. 6D shows the results of observation of the surface when the growth temperature is 650° C.

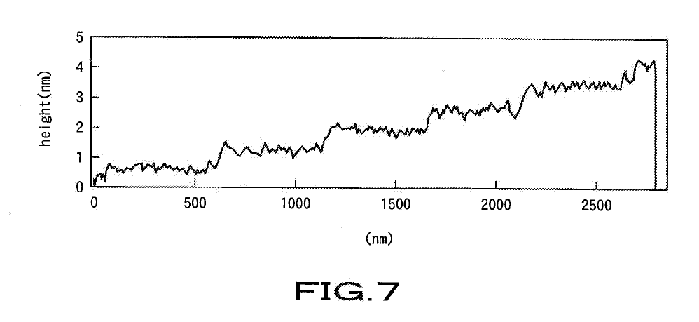

It is seen from FIGS. 6A to 6C that, when the growth temperature is 300° C. or lower, linear atomic steps have been formed in a regular order on the GaN surface. Meanwhile, the heights of the atomic steps for the ambient temperature, as measured by the atomic force microscope, were approximately 0.5 nm, as indicated in FIG. 7. It is noted that this figure indicates the heights of the range of the rectilinear lines of FIG. 6A. Also, EBSD measurements indicate that, in case the growth temperature is not higher than 300° C., the twist angle of the first GaN layer is 0.30 or less.

The fact that the atomic layers are formed in this manner indicates that the GaN atomic layers have been formed layer-by-layer in regular order.

In contrast, if the growth temperature is 650° C., no atomic steps are formed on the GaN surface, as shown in FIG. 6D. That is, the crystalline structure is not optimum.

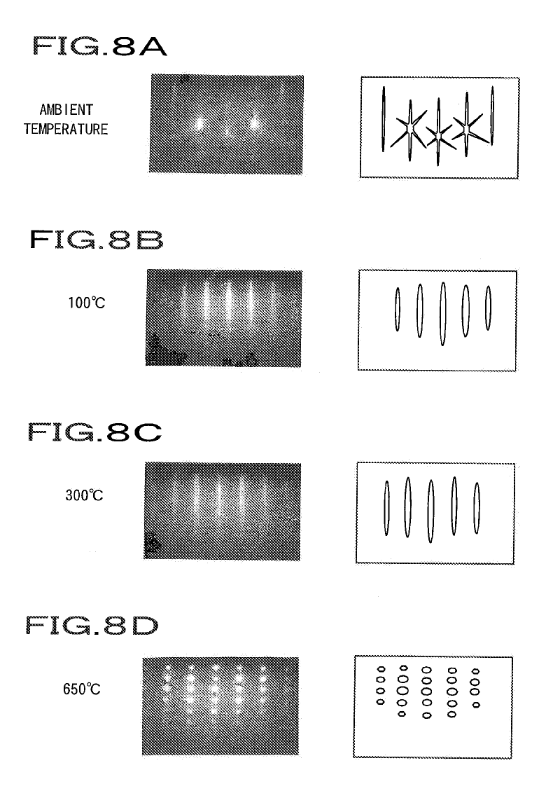

FIG. 8 shows the results of observation by the Reflection High Energy Electron Diffraction (RHEED) method of the surface of GaN formed on a surface of the ZnO substrate 11 planarized by the PLD method. Meanwhile, the left and right sides of FIG. 8 depict a view derived from a photo and a schematic view thereof, respectively.

FIG. 8(A) shows a RHEED image for a case where the growth temperature is ambient temperature, and FIG. 8(B) shows a RHEED image for a case where the growth temperature is 100° C. FIG. 8(C) shows a RHEED image for a case where the growth temperature is 300° C., and FIG. 8(C) shows a RHEED image for a case where the growth temperature is 650° C.

When the growth temperature is 300° C. or less, sharp streaky shapes (streaky patterns) may be noticed, as shown in FIGS. 8(A) to 8(C), indicating the growth of crystals of high quality.

In contrast, when the growth temperature is 650° C., no sharp streaky patterns are obtained, as shown in FIG. 8(D), indicating that the crystalline structure is not optimum.

It is seen from above that, by setting the growth temperature for GaN to 300° C. or less, the interfacial reaction with ZnO may be suppressed to allow epitaxial growth which takes advantage of lattice matching with ZnO.

In the low-temperature GaN film forming step S12, which is based on the PLD method, the initial growth rate is set to 10 nm/hour from the following consideration:

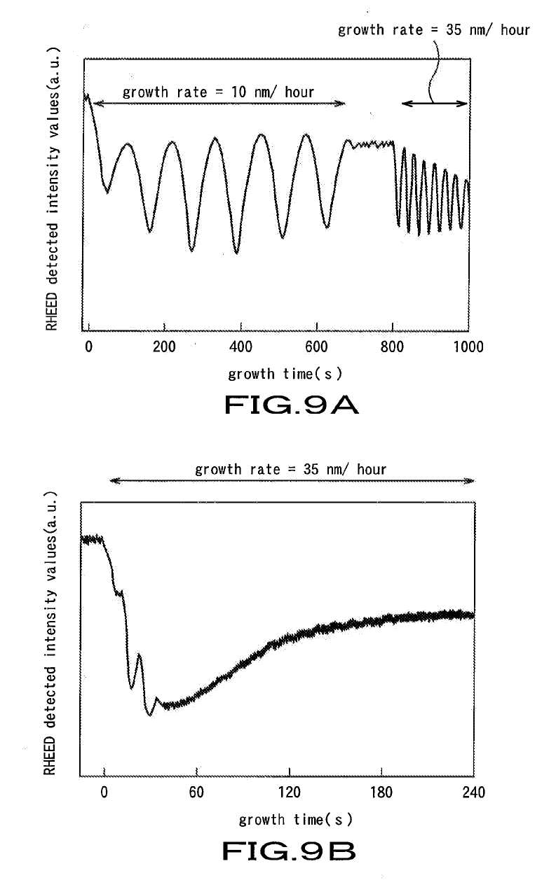

In the GaN vapor deposition step, carried out by the PLD method, status changes were measured in real-time, based on the Reflection High Energy Electron Diffraction (RHEED) method. The results of measurement are shown in FIG. 9.

FIG. 9(A) shows time changes of detected intensity values of the Reflection High Energy Electron Diffraction (RHEED) in case GaN is grown for 640 seconds, at a growth rate of 10 nm/hour, and GaN is then grown at a rate of 35 nm/hour, in the low-temperature film forming step S12. FIG. 9(B) shows time changes of detected intensity values of the Reflection High Energy Electron Diffraction (RHEED) in case GaN is grown at a rate of 35 nm/hour from the outset, in the low-temperature film forming step S12.

The graph of FIG. 9(A) indicates that, not only during the initial stage, with the growth rate of 10 nm/hour, but also during the subsequent stage, with the growth rate of 35 nm/hour, the RHEED detected intensity values are increased/decreased repeatedly at a fixed period. Each period stands for one atomic layer. Hence, five atomic layers of GaN have been formed during the initial stage with the growth rate of 10 nm/hour.

In contrast, when GaN is grown at a fast rate of 35 nm/hour from the outset, there is scarcely noticed the periodic waveform of increase/decrease of the detected intensity values of RHEED, as shown in FIG. 9(B). This indicates that the crystalline structure of GaN has collapsed.

That is, if, in allowing the growth of GaN on the planarized surface of the ZnO substrate 11, in accordance with the PLD method, a high rate of crystal growth of say 35 nm/hour is used from the initial stage, the crystal generated is lowered in quality. In contrast, if the low growth rate of say 10 nm/hour is used at an initial stage, the crystal formed is high in quality. This high crystal quality may be maintained even in case a high growth rate is used, provided that such high rate growth is preceded by a low rate growth of the order of five atomic layers.

Thus, if GaN is allowed to grow on the planarized surface of the ZnO substrate 11 in accordance with the PLD method for the low-temperature film-forming step S12, it is sufficient that GaN is allowed to grow in an initial stage at a growth rate not higher than 10 nm/hour, and to switch to a high growth rate after forming several atomic layers, for example, five atomic layers.

The PLD method is now described.

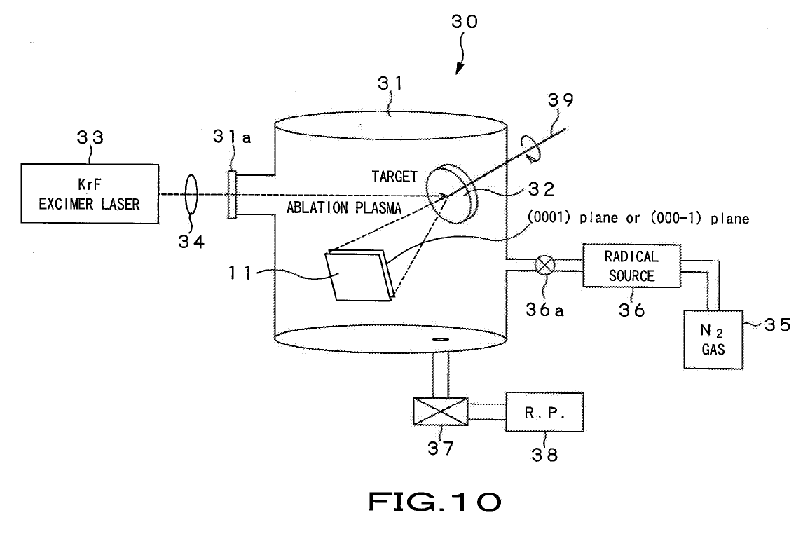

In the PLD method, a GaN layer 12 is deposited on the ZnO substrate 11, using a PLD device 30, shown in FIG. 10, for instance.

The PLD device 30 includes a chamber 31 that delimits a hermetically sealed space to maintain the pressure and the temperature of the gas charged therein. Within the chamber 31, there are arranged a ZnO substrate 11 and a target 32 facing each other. The target 32 is formed of metal gallium.

The PLD device 30 includes a KrF excimer laser 33 radiating a high output pulse laser with a wavelength of 248 nm. A pulse laser light beam, radiated from the KrF excimer laser 33, has its spot adjusted by a lens 34 so that its focal point will be in the vicinity of a target 32. The pulse laser light beam is incident at an angle of approximately 30° on the surface of the target 32, arranged within the chamber 31, via a window 31a provided in a lateral surface of the chamber 31.

The PLD device 30 also includes a gas supply part 35 for introducing a nitrogen gas into the chamber 31 and a nitrogen radical source 36 for turning the nitrogen gas into nitrogen radicals. The nitrogen radical source 36 transiently excites the nitrogen gas, supplied from the gas supply part 35, with the aid of the high repetition rate, and delivers the nitrogen radicals into the inside of the chamber 31. Between the chamber 31 and the gas supply part 35, there is provided an adjustment valve 36a for controlling the gas concentration for controlling the state of adsorption to the ZnO substrate 11 in relation with the nitrogen radical gas molecule and the wavelength of the pulsed laser light.

The PLD device 30 also includes a pressure valve 37 for controlling the pressure within the chamber 31 and a rotary pump 38. The pressure within the chamber 31 is controlled, as the process of the PLD method of forming a film under reduced pressure is taken into account, in such a manner that a preset pressure will be developed by the rotary pump 38 in e.g. a nitrogen atmosphere.

The PLD device 30 also includes a rotary axis 39 for allowing rotation of the target 32 to cause movement of a point illuminated by pulse laser light.

In the above-described PLD device 30, pulse laser light is intermittently illuminated on the target 32, run in rotation by the rotary axis 39, as the nitrogen gas remains charged in the chamber 31. This abruptly raises the temperature on the surface of the target 32, thus allowing generation of a Ga atom containing ablation plasma. The Ga atoms, contained in the ablation plasma, are subjected to a collision reaction with nitrogen atoms, and are moved towards the ZnO substrate 11, as the Ga atoms are progressively changed in their states. On arrival at the ZnO substrate 11, the Ga atom containing particles are directly diffused into the (0001) plane or the (000-1) plane on the ZnO substrate 11, and are formed into a thin film in the most stable state of the lattice matching.

The temperature of the ZnO substrate 11 at this time is set to 300° C. or lower.

This generates a GaN layer 12.

It should be noted that the technique of epitaxial growth of GaN in the low-temperature film-forming step S12 of the GaN layer is not limited to the PLD method. That is, the GaN layer may also be produced by other physical vapor deposition (PVD) methods, such as sputtering or the molecular beam epitaxy (MBE). The GaN layer may also be formed by a chemical vapor deposition (CVD) employing a MOCVD method, for instance, instead of by the physical vapor deposition (PVD) methods.

### (High-Temperature Film-Forming Step S13)

Then, in the high-temperature film-forming step S13, the second GaN layer 14 is epitaxially grown, by the PLD method, on the first GaN layer 13 formed by the low-temperature film-forming step S12. The temperature for GaN growth is set to 550° C. or higher.

The temperature for growth of the second GaN layer 14 is set to 550° C. or higher during the high-temperature film-forming step S13 because point defects at the time of epitaxial growth of the GaN layer may be sufficiently suppressed at this temperature.

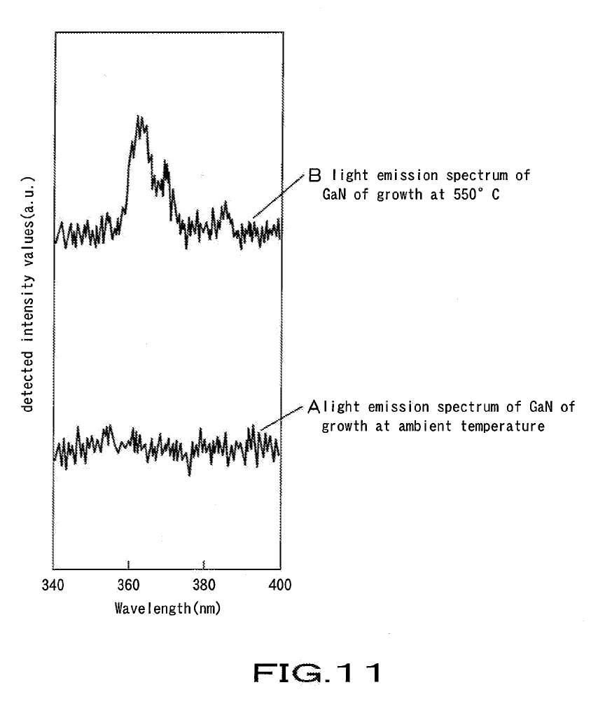

FIG. 11 depicts a graph showing repetition rate characteristics of the light volume generated in case of illumination of a HeCd laser on a GaN film. Specifically, A in FIG. 11 depicts characteristics in case the HeCd laser is illuminated on a GaN crystal grown at ambient temperature, whereas B in FIG. 11 depicts characteristics in case the HeCd laser is illuminated on a GaN crystal grown at 550° C. In this manner, the GaN film, grown at ambient temperature, contains many point defects, so that excited carriers are non-radiatively re-combined, and hence no light emission is noticed. Conversely, light emission may be observed with crystal grown at 550° C., indicating an extremely small quantity of point defects. In short, fine grains generated at the time of film deposition by the low-temperature film-forming step S12 have fused together and disappeared by the high-temperature film-forming step S13.

Meanwhile, the PLD method at the high-temperature film-forming step S13 is the same as the method used at the low-temperature film-forming step S12. That is, the GaN film is formed with the PLD device 30, even in the high-temperature film-forming step S13. It should be noted however that, in the high-temperature film-forming step S13, the temperature of the ZnO substrate 11 is set to 550° C. or higher.

The technique of epitaxial growth of GaN at the high-temperature film-forming step S13 is not limited to the PLD method. That is, the GaN layer may also be produced by other physical vapor deposition (PVD) methods, such as molecular beam epitaxy (MBE) or sputtering. The GaN layer may also be formed by a chemical vapor deposition (CVD) employing a MOCVD method, for instance, instead of by the physical vapor deposition (PVD) methods.

### (Specified Example of Fabrication of the GaN Layer and Results of Measurement Thereof)

Specifically, a GaN layer 12 was grown by epitaxy under the following conditions, for instance.

In the low-temperature film-forming step S12, a target 32 is formed of metal Ga with 99.99% purity. The target 32 was placed parallel to the (0001) plane or the (000-1) plane in the ZnO substrate 11. As nitrogen source, an RF plasma radical nitrogen source was used at 320 W and the growth pressure was set to 8×10⁻⁶ Torr. The pulse repetition rate of the pulse laser light radiated from the KrF excimer laser 33 was set to 10 Hz, and its energy density was set to 1˜3 J/cm². The growth rate of the GaN layer 12 was set to 10 nm/hour.

In the low-temperature film-forming step S12, the substrate temperature of the ZnO substrate 11 was set to ambient temperature.

In the high-temperature film-forming step S13, the target 32 formed of metal Ga with 99.99% purity was used. The target 32 was placed parallel to the (0001) plane or the (000-1) plane in the ZnO substrate 11. As nitrogen source, an RF plasma radical nitrogen source was used at 320 W and the growth pressure was set to 8×10⁻⁶ Torr. The pulse repetition rate of the pulse laser light radiated from the KrF excimer laser 33 was set to 50 Hz, and its energy density was set to 1˜3 J/cm². The growth rate of the GaN layer 12 was set to 35 nm/hour.

In the high-temperature film-forming step S13, the substrate temperature of the ZnO substrate 11 was set to 650° C.

X ray diffractometry was carried out for the so generated nitride semiconductor device 10.

In observing 0002 diffraction, the semiconductor device 10 was rotated, and measurement was made of the X-ray intensity for each angle of rotation in question. A chevron-shaped curve was obtained. The ½ value (half-value width) of the peak of the X-ray intensity for −2024 diffraction was 0.09°.

Thus, it is seen that, according to the present invention, the GaN film 12, having a planarized surface, may be formed.

Meanwhile, in case the GaN film was not formed in the low-temperature film-forming step S12, that is, in case GaN by the PLD method at 650° C. was directly grown by epitaxy on the ZnO substrate 11, the half-value width of X-ray intensity for the 0002 diffraction was on the order of 0.50, while that of the −2024 diffraction was on the order of 0.7°. In this manner, in case the GaN layer is not formed in the low-temperature film forming step S12, a GaN layer with a roughed surface is formed.

### Second Embodiment

A process for fabrication of a semiconductor according to a second embodiment is now described.

### (Constitution of Semiconductor)

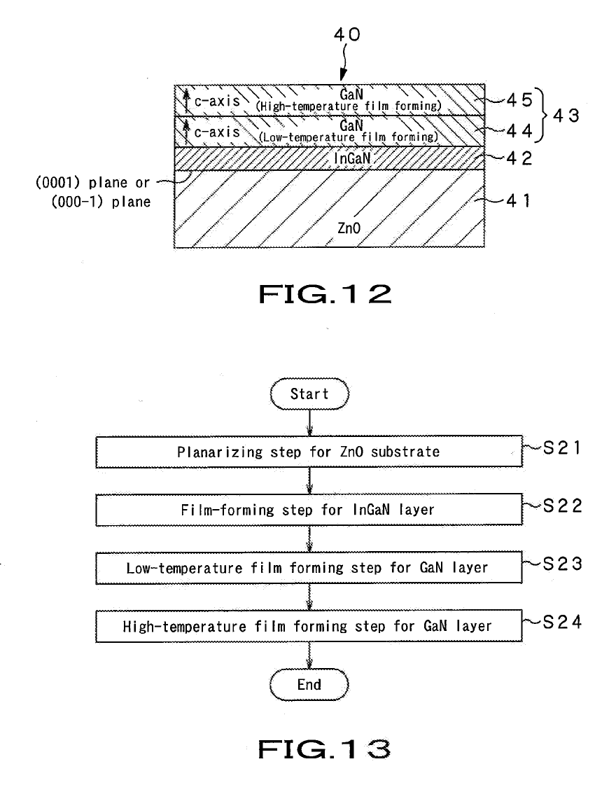

In a semiconductor device fabrication process of a second embodiment, an InGaN layer 42 is formed on a ZnO substrate 41, and a GaN layer 43 is further formed thereon to form a nitride semiconductor device 40, as shown in FIG. 12.

The nitride semiconductor device 40 includes an InGaN layer 42 oriented so that a c-axis of InGaN is perpendicular to the (0001) plane or the (000-1) plane of the ZnO substrate 41 formed of ZnO. The nitride semiconductor device 40 also includes, on top of the InGaN layer 42, a GaN layer 43 oriented so that a c-axis of GaN is perpendicular to the (0001) plane or the (000-1) plane of the ZnO substrate 41. The GaN layer 43 also includes a first GaN layer 44, formed by epitaxial growth on the InGaN layer 42 at a low temperature (320° C. or lower), and a second GaN layer 45, formed by epitaxial growth on the first GaN layer 44 at a high temperature (550° C. or higher).

Since ZnO and InGaN are equal to each other in the lattice constant, it become possible to diminish lattice mismatch to as small a value as possible.

### (Overall Flow)

The respective steps for fabrication of the nitride semiconductor device 40 will now be described.

In fabricating the nitride semiconductor device 40, a step of planarizing the ZnO substrate (S21), a step of forming an in GaN layer (S22), a step of low-temperature film forming of the GaN layer (S23) and a step of high-temperature film-forming of the GaN layer (S24), as shown in FIG. 13.

### (Planarizing Step S21)

In the planarizing step S21, the same processing as the planarizing step S11 of the above-described first embodiment is carried out.

### (InGaN Film Forming Step S22)

Next, in the InGaN forming step S22, InGaN is grown by epitaxy, by the PLD method, on a planarized surface of the ZnO substrate 41, to form an InGaN layer 42.

The lattice constant of InGaN is closer to that of ZnO than to that of GaN. Hence, with this in GaN layer 42, provided between the GaN layer and the ZnO substrate, it is possible to improve the crystalline properties of the GaN layer.

The PLD method used is the same as the method used for the first embodiment, provided that the target 32 placed in the chamber 31 is metal InGa.

The InGaN layer may also be formed, not by the PLD method, but by a physical vapor deposition, such as MBE method, or by a chemical vapor deposition (CVD) method.

### (Low-Temperature Film-Forming Step S23)

Next, in a low-temperature film-forming step S23, a first GaN layer 44 is grown by epitaxy on the InGaN layer 42, in accordance with the PLD method. At this time, the temperature at the time of growth of GaN is set to 320° C. or less.

The temperature at the time of growth of the first GaN layer 44 is set to 320° C. or less because InGaN is weak against heat and hence a GaN film cannot be formed at higher temperatures. That is, with the temperature at the time of growth of GaN set to 320° C. or less, a GaN film can be formed without destructing InGaN.

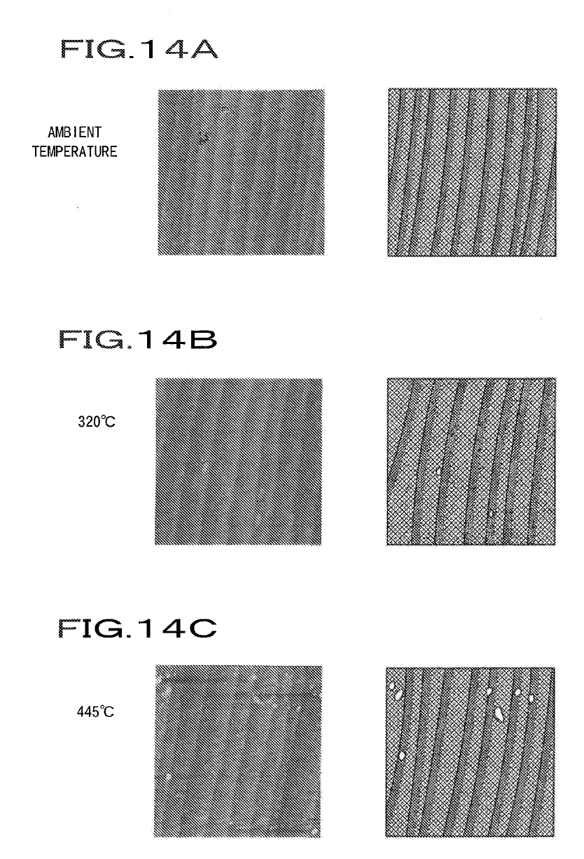

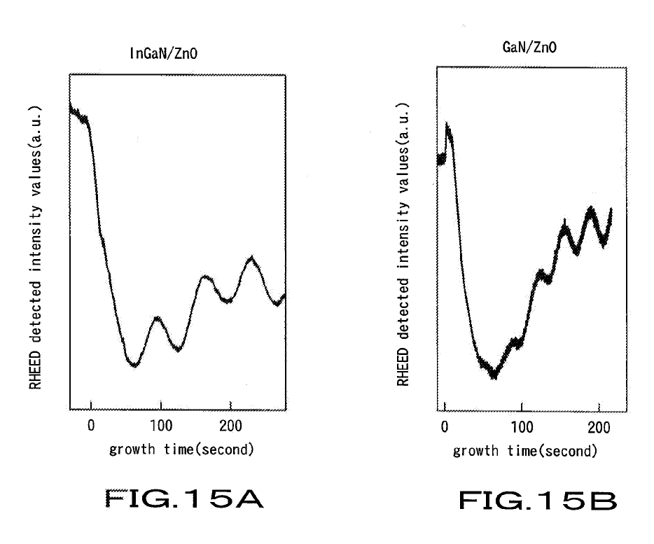

FIG. 14 shows the surface state of InGaN when InGaN (In: 20%; GaN: 60%), formed in the step S22, is processed by heating in ultrahigh vacuum. Meanwhile, the left and right sides of FIG. 14 depict a view derived from a photo and a schematic view thereof, respectively.

FIG. 14(A) shows surface states of InGaN at ambient temperature. FIGS. 14(B) and 14(C) show the surface states of InGaN at 320° C. and at 445° C., respectively. It is seen from these figures that, at ambient temperature and at 320° C., InGaN has been decomposed and the surface is scarcely roughed, whereas, at 445° C., InGaN has been decomposed and the surface has been roughed. Hence, in the low-temperature film-forming step S23, the temperature at the time of growth of GaN is set to 320° C. or lower.

The PLD method is the same as the method used in the low-temperature film forming step S12 of the first embodiment.

### (High-Temperature Film-Forming Step S24)

Next, in a high-temperature film-forming step S24, the second GaN layer 45 is formed by epitaxy, in accordance with the PLD method, on the first GaN layer 44 formed in the low-temperature film-forming step S24. The temperature at the time of growth of GaN is set to 550° C. or higher.

The temperature at the time of growth of GaN is set to 550° C. or higher in the high-temperature film-forming step S24 because the point defect may sufficiently be suppressed from being generated at the time of epitaxial growth of the GaN layer.

That is, the fine grains generated on low-temperature film forming in the low-temperature film-forming step S23 become fused and extinct.

It should be noted that the GaN layer has already been formed on the InGaN layer 42 by the low-temperature film-forming step S23 and hence is not affected by heat.

The PLD method used is the same as that used in the high-temperature film-forming step S13 of the first embodiment, viz. the GaN layer is formed using the PLD device 30 in the high-temperature film-forming step S24 as well.

### (Specified Example of Fabrication of the GaN Layer and Results of Measurement Thereof)

Specifically, the InGaN layer 42 and the GaN layer 43 were grown by epitaxy under the following conditions:

In the InGaN film-forming step S22, the target 32 was formed of metal InGa (In: 18%; Ga: 82%). The target 32 was placed parallel to the (0001) plane or to the (000-1) plane of the ZnO substrate 41. An RF plasma radical nitrogen source at 320 W was used as a nitrogen source and the growth pressure was set to 8×10⁻⁶ Torr. The pulse repetition rate and the energy density of the pulse laser light, radiated by the KrF excimer laser 33, were set to 10 Hz and to 1˜3 J/cm², respectively. In the InGaN film-forming step S22, the substrate temperature of the ZnO substrate 41 was set to ambient temperature.

In the InGaN film-forming step S22, InGaN was deposited by five atomic layers.

In the low-temperature film forming of the GaN layer (S23), the target 32 was formed of metal Ga (purity 99.99%). The target 32 was placed parallel to the (0001) plane or to the (000-1) plane of the ZnO substrate 41. An RF plasma radical nitrogen source at 320 W was used as a nitrogen source and the growth pressure was set to 8×10⁻⁶ Torr. The pulse repetition rate and the energy density of the pulse laser light, radiated by the KrF excimer laser 33, were set to 10 Hz and to 1˜3 J/cm², respectively. The growth rate of the GaN layer 44 was 10 nm/hour.

In the low-temperature film-forming step S23, the substrate temperature of the ZnO substrate 41 was set to ambient temperature.

In the low-temperature film-forming step S23 for GaN, GaN was deposited to 10 nm.

In the high-temperature film-forming step S24, the target 32 was formed of metal Ga (purity 99.99%). The target 32 was placed parallel to the (0001) plane or to the (000-1) plane of the ZnO substrate 41. An RF plasma radical nitrogen source at 320 W was used as a nitrogen source and the growth pressure was set to 8×10⁻⁶ Torr. The pulse repetition rate and the energy density of the pulse laser light, radiated by the KrF excimer laser 33, were set to 10 Hz and to 1˜3 J/cm², respectively. The growth rate of the GaN layer was 35 nm/hour.

In the high-temperature film-forming step S24, the substrate temperature of the ZnO substrate 41 was set to 650° C.

X-ray diffractometry was carried out for the so generated nitride semiconductor device 40.

In observing 0002 diffraction, the semiconductor device 40 was rotated, and measurement was made of the X-ray intensity for each angle of rotation in question. A chevron-shaped curve was obtained. The ½ value (half-value width) of the peak of the X-ray intensity for 0002 diffraction was 0.029°. In observing −2024 diffraction, the nitride semiconductor device 40 was rotated, and measurement was made of the X-ray intensity for each angle of rotation in question. A chevron-shaped curve was obtained. The ½ value (half-value width) for the peak of the X-ray intensity for −2024 orientation was 0.079°.

The half-value width of the X-ray intensity of 0002 diffraction of GaN, currently mass-produced using the MOCVD method, is on the order of 0.1°, while the half-value width of the X-ray intensity of −2024 diffraction is on the order of 0.11°, thus indicating marked improvement of characteristics of the GaN layer.

If, after forming the InGaN layer 42, the high-temperature film-forming step S24 is directly carried out without the intermediary of the low-temperature film-forming step S23 for GaN, the half-value width of the 0002 diffraction of GaN is 0.4°, while the half-value width of the −2024 diffraction is 0.6°. This indicates that the characteristics of the GaN layer are inferior, such that it is necessary to carry out the low-temperature film-forming step S23 for GaN.

Also, in the process of vapor deposition of InGaN and GaN, in accordance with the PLD method, status changes were measured in real-time in accordance with the RHEED (Reflection High Energy Electron Diffraction) method.

The results are shown in FIG. 15(A). Meanwhile, FIG. 15(B) depicts a control example. This control example shows results of measurement for the case in which film forming of the InGaN layer in the InGaN film-forming step S22 was not carried out, that is, for the case in which GaN has been directly grown by epitaxy at ambient temperature on the ZnO substrate 41.

In both the graphs of FIGS. 15(A) and 15(B), increase/decrease of the detected intensity values of the RHEED (Reflection High Energy Electron Diffraction) is repeated at a constant period. This period stands for one atomic layer. In short, it is seen that, if the InGaN layer or the GaN layer is formed in accordance with the present invention, atomic layers are formed in order on the layer-by-layer basis.

It should be noted however that periodic increase/decrease in the graph of FIG. 15(A) is more definite. In short, it is seen that the crystalline structure is less liable to become collapsed in case InGaN is formed on ZnO.

### Third Embodiment

A semiconductor fabrication process of a third embodiment is now described.

### (Constitution of the Semiconductor)

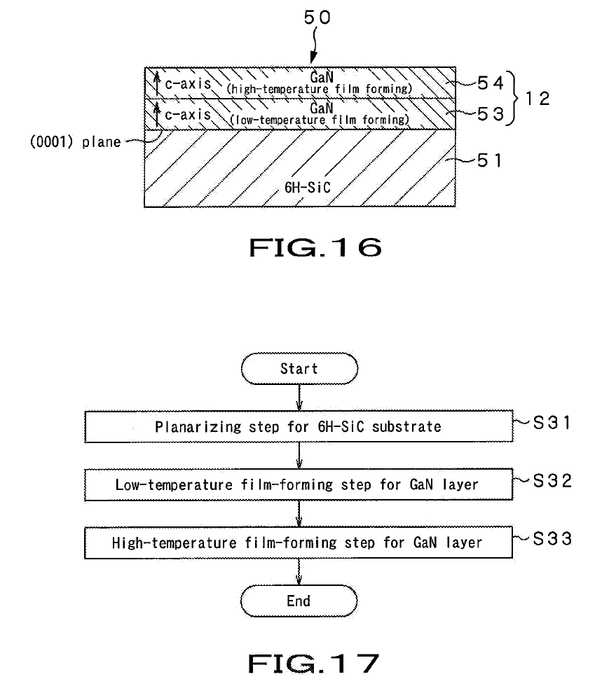

In the third embodiment of the fabrication process for the semiconductor device, a nitride semiconductor device 50, having a GaN layer 52 formed on a 6H—SiC (0001) substrate 51, as shown in FIG. 16, is prepared.

The nitride semiconductor device 50 includes the GaN layer 52, which is oriented so that a c-axis of GaN, as a hexagonal crystal, is perpendicular to the (0001) plane of the 6H—SiC substrate 51, as shown in FIG. 16. This GaN layer 12 is made up of a first GaN layer 53 and a second GaN layer 54. The first GaN layer 53 is formed by epitaxial growth on the 6H—SiC substrate 51 at a lower temperature (300° C. or higher), whereas the second GaN layer 54 is formed by epitaxial growth on the first GaN layer 53 at a higher temperature (550° C. or higher).

6H—SiC, making up the 6H—SiC substrate 51, has a wurtzitic crystalline structure, with its lattice constant a being such that a=3.08 Å, whereas GaN, making up the GaN layer 52, has a wurtzitic crystalline structure (see FIG. 2), with its lattice constant a being such that a=3.189 Å.

Since lattice mismatch of 6H—SiC and GaN, comprised of the above-described crystalline structure, is small and is 3.5%, it is possible to have GaN of high crystalline properties grown by epitaxy on the 6H—SiC substrate 51. Also, since the 6H—SiC substrate 51 is electrically conductive, it is possible to fabricate a semiconductor in which 6H—SiC itself acts as an electrode.

### (Overall Flow)

The entire process for fabrication of the nitride semiconductor device 50 is now described.

Referring to FIG. 17, the method for fabrication of the nitride semiconductor device 50 is divided into a step of planarizing a 6H—SiC substrate (S31), a step of low-temperature film forming of a GaN layer (S32) and a step of high-temperature film forming of a GaN layer (S33).

### (Planarizing Step S31)

Initially, in the planarizing step S31, a 6H—SiC substrate 51 is sliced so that the substrate surface will become the (0001) plane.

The (0001) plane of the 6H—SiC substrate 51, thus sliced, is then processed with CMP (Chemical Mechanical Polishing). This processing is carried out by mechanical polishing using diamond slurries, for instance. Specifically, the mechanical polishing is carried out using a set of diamond slurries whose particle size differs from one diamond slurry to the next. The diamond slurries with progressively smaller particle sizes are used as the mechanical polishing is continued, until ultimately the diamond slurry of the particle size of approximately 0.5 μm is used to realize mirror surface polishing. Further, colloidal silica is used preferably for polishing until the polished surface has been planarized to the RMS of the surface roughness not larger than 10 Å. The 6H—SiC substrate 51, thus mechanically polished, is heat-treated, using a high-temperature oven controlled to a temperature 800° C. or higher and to an atmosphere of a hydrogen/helium mixture. This yields the 6H—SiC substrate 51 planarized to the atomic level.

### (Low-Temperature Film-Forming Step S32)

In a low-temperature film-forming step S32, the first GaN layer 53 is grown by epitaxy, by the PLD method, on the surface of the 6H—SiC substrate 51, planarized by the step S31. The PLD method is the same as that of the first embodiment, provided that the substrate placed within the chamber 31 is the 6H—SiC substrate 51.

The temperature at the time of growth of GaN is set to 300° C. or lower. The initial growth rate at the time of generation of the first GaN layer is set to 10 nm/hour. By so doing, no interfacial reaction takes place at an interface between 6H—SiC and GaN, so that no interface reaction layer is generated.

### (High-Temperature Film-Forming Step S33)

In the high-temperature film-forming step S33, the second GaN layer 54 is allowed to grow epitaxially, by the PLD method, on the first GaN layer 53 formed in the low-temperature film-forming step S32. At this time, the temperature at the time of growth of the second GaN layer is set to 550° C. or higher. By so doing, it is possible to sufficiently suppress point defects from being generated at the time of growth of the second GaN layer 54. Also, fine grains generated at the time of film deposition by the low-temperature film-forming step S32 become fused together and disappear at this time. In case the growth temperature is set to 800° C. or higher, GaN is vaporized off so that no crystal may be produced. Meanwhile, in the epitaxial growth of the second GaN layer 54 in the step S33, the physical vapor deposition (PVD), such as MBE, or a MOCVD method, may be used in place of the PLD method.

### (Results of Measurement)

The epitaxial growth of GaN on the 6H—SiC substrate, heat-treated in the planarizing step S31, was compared to that on the non-heat-treated 6H—SiC substrate.

For pre-processing a substrate, the heat-treated 6H—SiC (0001) substrate was processed with CMP (Chemical Mechanical Polishing), rinsed with alcohol and wet-etched with a 3% fluoric acid-hydrochloric acid. The so processed substrate was then heat-treated at 1300° C. for 20 minutes in a hydrogen/helium mixed gas. The substrate was then introduced into an ultra-vacuum chamber and subjected to Ga-flashing, before growth of GaN, to remove a surface oxide film.

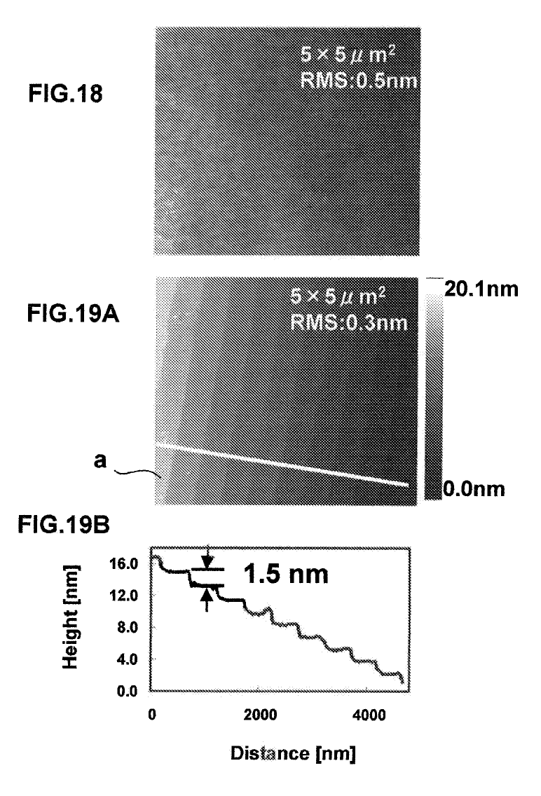

FIG. 18 shows the results of observation of the 6H—SiC (0001) substrate surface following CMP processing. FIG. 19(A) shows the results of observation of the 6H—SiC (0001) substrate surface that was heat-treated after the CMP processing. It is seen from these results that a step-and-terrace structure may be noticed as the result of the heat treatment. Also, a substrate surface, planar to the atomic level, and having a step height of approximately 1.5 nm, corresponding to one unit cell of 6H—SiC, could be noticed from the cross-sectional profile of a line a shown in FIG. 19(B).

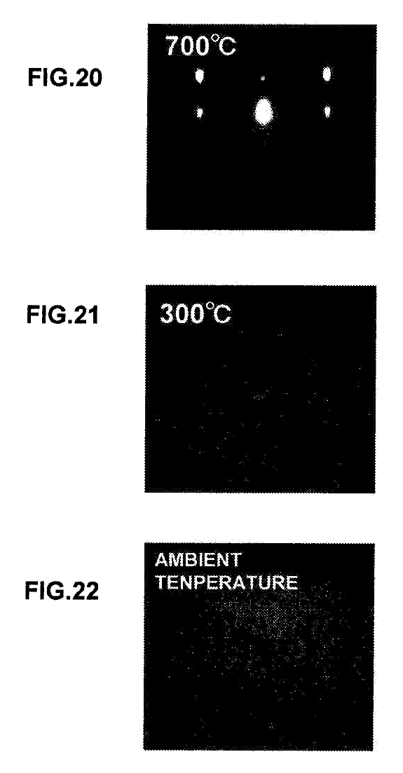

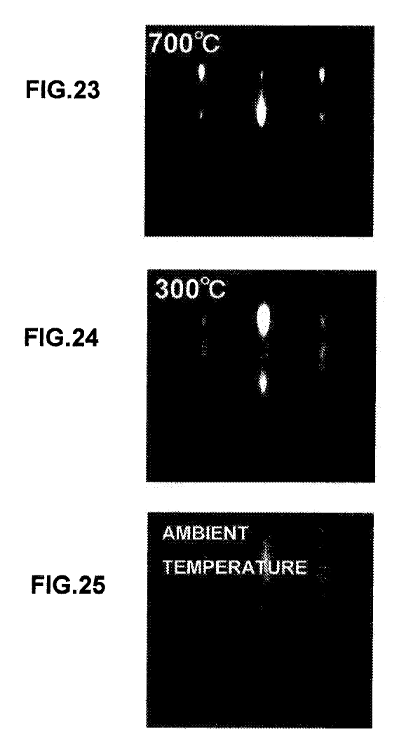

FIGS. 20 to 22 show RHEED patterns obtained on allowing GaN to grow at 700° C., 300° C. and at ambient temperature, to a film thickness of approximately 200 nm on a 6H—SiC (0001) substrate processed only with CMP processing, respectively. When GaN was allowed to grow at a substrate temperature of 700° C., the RHEED pattern was a spotty pattern suggestive of 3D growth, as shown in FIG. 20, testifying to epitaxial growth. Conversely, when GaN was allowed to grow at a lower substrate temperature of 300° C. and at ambient temperature, the corresponding RHEED patterns were a ring pattern, indicating polycrystalline growth, as shown in FIG. 21, and a hallo pattern, indicating an amorphous state, as shown in FIG. 22. In both of these cases, no epitaxial growth occurs. It is seen from these results that epitaxial growth of the GaN thin film at a low temperature range is difficult to take place on the 6H—SiC substrate subjected only to CMP processing. FIGS. 23 to 25 show RHEED patterns obtained on allowing the growth of GaN at 700° C., 300° C. and at ambient temperature, on a 6H—SiC (0001) substrate subjected to the aforementioned CMP processing followed by heat treatment. Referring to FIG. 23, when GaN was allowed to grow at a substrate temperature of 700° C., a spotty pattern similar to the RHEED pattern, subjected only to the CMP processing, as shown in FIG. 20, was obtained. When GaN was allowed to grow at a substrate temperature of 300° C., a spotty pattern, suggestive of 3D growth, was obtained. When GaN was allowed to grow at ambient temperature, a streaky pattern, suggestive of a 2D growth, was obtained, thus indicating that epitaxial growth of a GaN thin film was taking place. In short, it could be seen that, on a SiC substrate, planar to the atomic level, the epitaxial growth of GaN in the totality of temperature domains from ambient to 700° C. was possible. This may be attributed to the fact that use of a substrate planar to the atomic level leads to promotion of surface diffusion of atoms on the substrate surface.

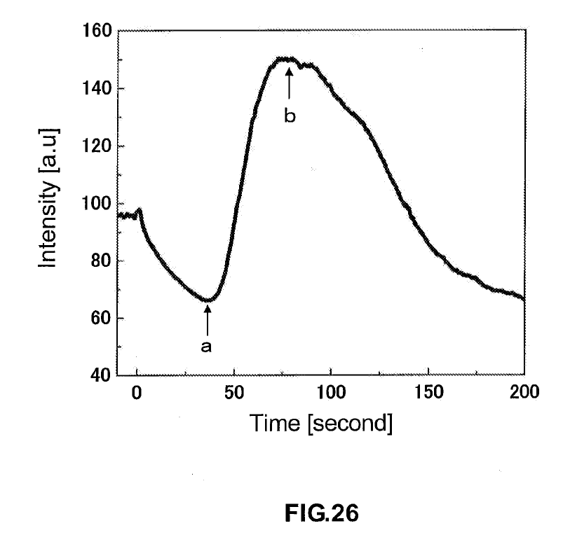

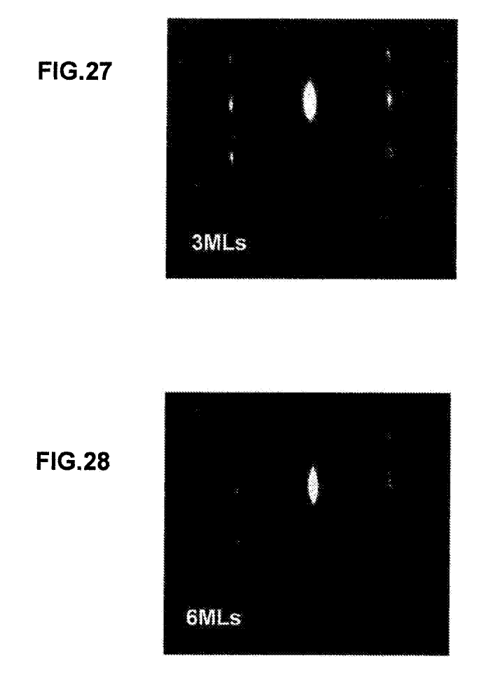

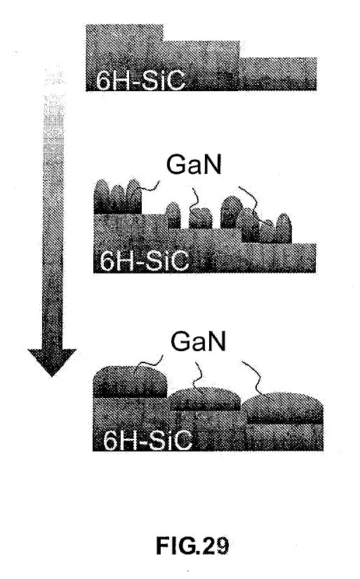

The growth mode at variable growth temperatures was then analyzed by in-situ RHEED observation in the initial stage of growth on a heat-treated 6H—SiC substrate that is planar to the atomic level. FIG. 26 shows an intensity profile of a RHEED specular spot for high-temperature growth at 700° C. FIG. 27 shows a RHEED image at a point a of FIG. 26, that is, for a film thickness 3 ML of the GaN thin film, whereas FIG. 28 shows a RHEED image at a point b of FIG. 26, that is, for a film thickness 6 ML of the GaN thin film. Since the RHEED images for the film thicknesses of 3 ML and 6 ML of the GaN thin film indicate spotty patterns, it may be seen that 3D growth is taking place at 700° C. From the intensity profile, shown in FIG. 26, it may also be seen that 3D growth is taking place from the initial growth stage for 700° C. That is, as may be seen from the schematics of crystalline growth, shown in FIG. 29, 3D island-like growth occurs as from the initial growth stage, in case of high-temperature growth at 700° C., thus roughing the surface.

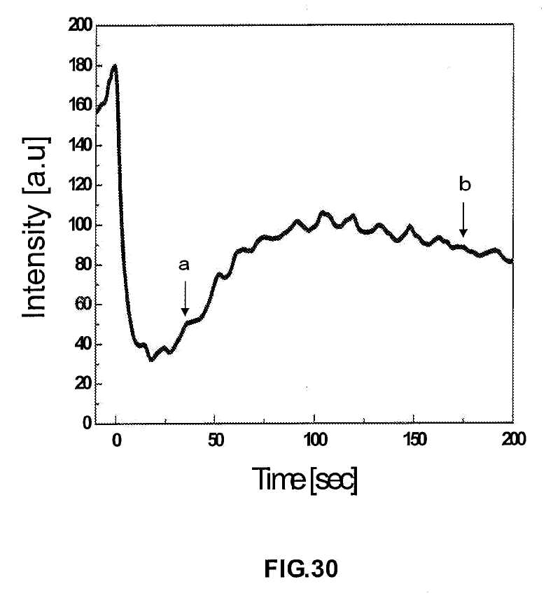

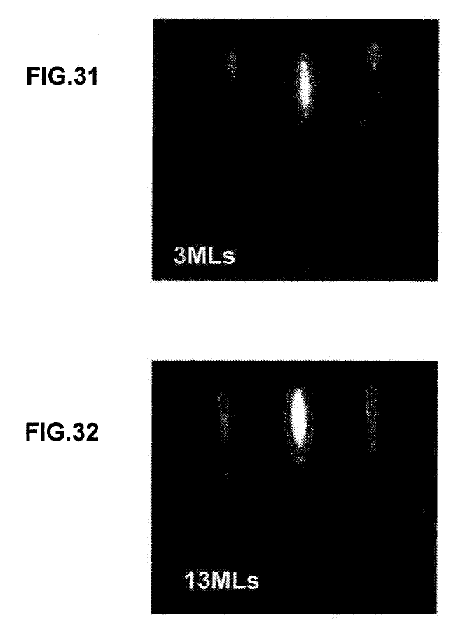

The case in which a GaN thin film was allowed to grow at ambient temperature on a heat-treated 6H—SiC substrate which was planar to the atomic level. FIG. 30 shows an intensity profile of a RHEED specular spot for growth at ambient temperature. FIG. 32 shows a RHEED image at a point a of FIG. 30, that is, for a film thickness 3 ML of the GaN thin film, whereas FIG. 32 shows a RHEED image at a point b of FIG. 30, that is, for a film thickness 13 ML of the GaN thin film. Since FIGS. 31 and 32 show streaky patterns of the RHEED images for the film thicknesses of 3 ML and 13 ML of the GaN thin film, respectively, it may be seen that, unlike the case of growth at a high temperature, it is seen that 2D growth is taking place.

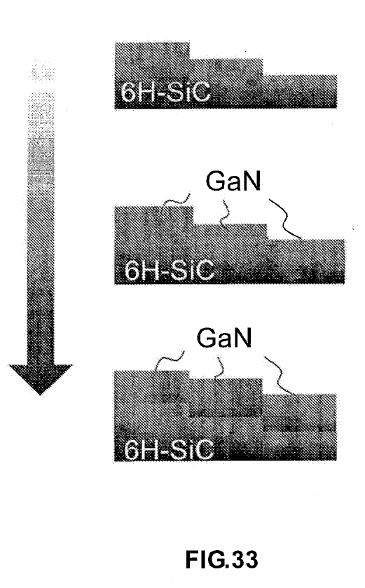

It is also seen, from the RHEED profile, shown in FIG. 30, that the growth of the GaN thin film is taking place in a layer-by-layer mode, as shown in FIG. 33. This may be attributable to the fact that the growth at ambient temperature has led to increased density of nucleation of GaN.

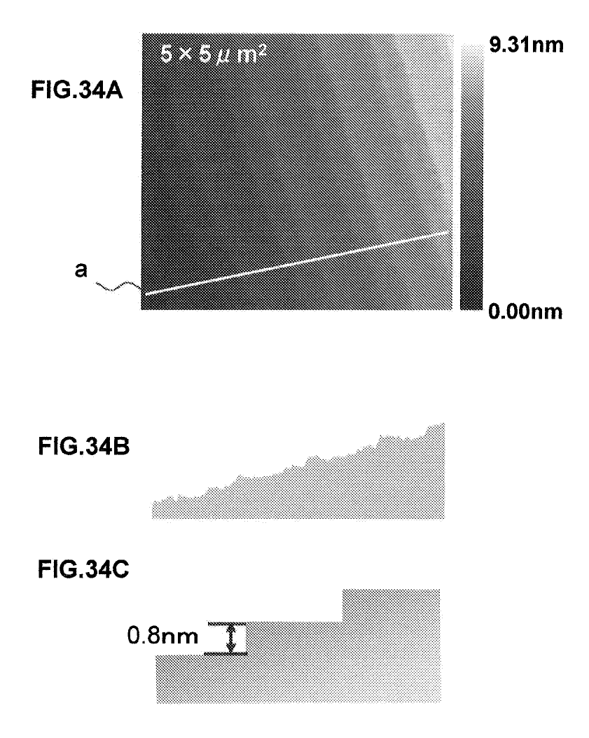

FIG. 34(A) shows an AFM image of a GaN thin film grown to 9 nm at ambient temperature. It is seen from the noticed AFM results that the GaN crystal grown at ambient temperature presents a surface of a step-and-terrace structure which is flat to the atomic level. Also, from the cross-sectional profile of a line a shown in FIG. 34(B), the step height was approximately 0.8 nm equivalent to 3 ML of GaN (see FIG. 34(C)).

Thus, if GaN is allowed to grow at a temperature not higher than 300° C., on a 6H—SiC substrate, which is flat to the atomic level, 2D layer-by-layer growth is continued and, since the crystal presents a surface of a step-and-terrace structure, which is flat to the atomic level surface, a high quality crystal may be obtained even with the growth at a temperature of 550° C. or higher in the high-temperature film-forming step S33.

It should be noted that not only 6H—SiC, explained in the above embodiment, but also a 4H—SiC or 3C—SiC substrate, similar in properties, such as in-plane lattice constant, to the 6H—SiC substrate, also permits growth of a GaN crystal having high crystalline properties.

### Fourth Embodiment

The semiconductor device fabrication process of a fourth embodiment is now described.

### (Constitution of the Semiconductor)

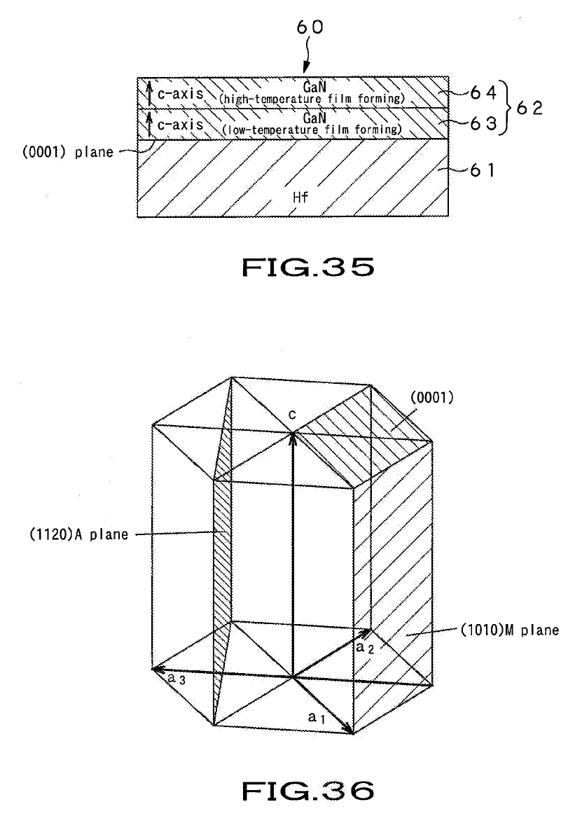

In the fourth embodiment of the fabrication process for the semiconductor device, a nitride semiconductor device 60, having a GaN layer 62 formed on a Hf (0001) substrate 61, as shown in FIG. 35, is prepared.

The nitride semiconductor device 60 includes a GaN layer 62, which is oriented so that a c-axis of GaN, as a hexagonal crystal, is perpendicular to the (0001) plane of the Hf substrate 61, formed of Hf, as shown in FIG. 35. This GaN layer 62 is made up of a first GaN layer 63 and a second GaN layer 64. The first GaN layer 63 is formed by epitaxial growth on the Hf substrate 61 at a lower temperature (300° C. or lower), whereas the second GaN layer 54 is formed by epitaxial growth on the first GaN layer 63 at a higher temperature (550° C. or higher).

Hf that makes up the Hf substrate 61 has a crystalline structure of a hexagonal close-packed structure, with its lattice mismatch with respect to GaN being as small as 0.3% in the in-plane direction and 2.4% in the c-axis direction. Moreover, Hf has the thermal expansion coefficient which is small and is 5.5%. Hence, the Hf substrate is efficacious in order to allow epitaxial growth of GaN of high crystalline performance. In particular, since Hf and GaN exhibit small mismatch in the c-axis direction, it becomes possible to allow the growth of GaN of high crystalline performance on a non-polar surface showing high light emitting properties. In particular, Hf allows epitaxial growth on a (−1-120) plane (A-plane), perpendicular to the a-axia, or on a (1010) plane (M-plane) which is an outer wall of the crystalline structure, as shown in FIG. 36. The following presupposes that GaN is allowed to grow on the (0001) plane.

### (Overall Flow)

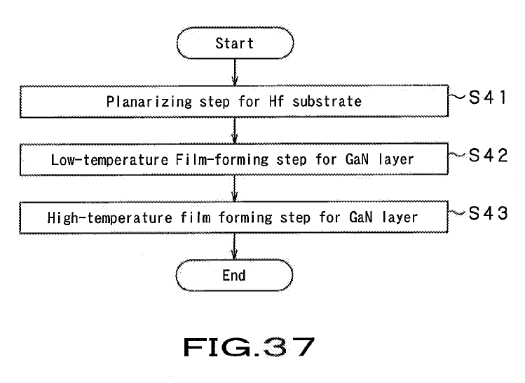

The respective steps for fabricating the nitride semiconductor device 60 is now described with reference to a flowchart shown in FIG. 37.

As in the first embodiment, the method for fabricating the nitride semiconductor device 60 is divided into a step of planarizing an Hf substrate (S41), a step of low-temperature film forming of a GaN layer (S42) and a step of high-temperature film forming of a GaN layer (S43).

### (Planarizing Step S41)

In the planarizing step S41, the Hf substrate 61 is sliced so that the substrate surface will become the (0001) plane.

The (0001) plane of the Hf substrate 61, thus sliced, is mechanically polished using diamond slurries, for instance. Specifically, the mechanical polishing is carried out using a set of diamond slurries differing in particle size from one diamond slurry to the next. The diamond slurries with progressively smaller particle sizes are used as the mechanical polishing is continued, until ultimately the diamond slurry of the particle size of approximately 0.5 μm is used to realize mirror surface polishing. Further, colloidal silica is preferably used for polishing until the polished surface has been planarized to the RMS of the surface roughness not larger than 10 Å. The Hf substrate 51, thus mechanically polished, is heat-treated, using a high-temperature oven at a temperature of 800° C. or higher and in an atmosphere of a hydrogen/helium mixture. This yields the Hf substrate 61 planarized to the atomic level.

### (Low-Temperature Film-Forming Step S42)

In a low-temperature film-forming step S42, the first GaN layer 63 is grown by epitaxy, by the PLD (Pulse Laser Deposition) method, on the surface of the Hf substrate 61, planarized by the step S41. The PLD method is the same as that of the first embodiment, provided that the substrate placed within the chamber 31 is the Hf substrate 61.

The temperature at the time of growth of GaN is set to 300° C. or lower. The initial growth rate at the time of generation of the first GaN layer is set to 10 nm/hour. By so doing, no interfacial reaction takes place at an interface between Hf and GaN, so that no interface reaction layer is generated.

### (High-Temperature Film-Forming Step S43)

In the high-temperature film-forming step S43, the second GaN layer 64 is allowed to grow epitaxially, by the PLD method, on the first GaN layer 63 formed in the low-temperature film-forming step S42. The temperature at the time of growth of the second GaN layer is set to 550° C. or higher. By so doing, point defects may sufficiently be prevented from being generated at the time of growth of the second GaN layer 64. Also, fine grains generated at the time of film deposition by the low-temperature film-forming step S42 become fused together and disappear at this time. In case the growth temperature is set to 800° C. or higher, GaN is vaporized off so that no crystal may be produced. Meanwhile, in the epitaxial growth of the second GaN layer 64 in the step S43, the physical vapor deposition (PVD), such as MBE, or a MOCVD method, may be used in place of the PLD method.

### (Results of Measurement)

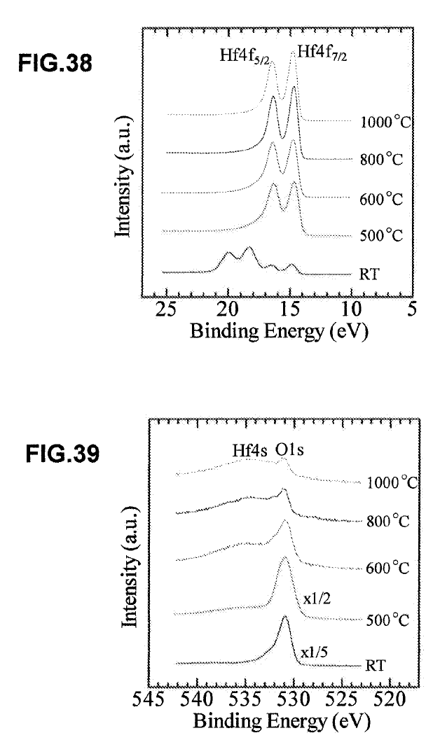

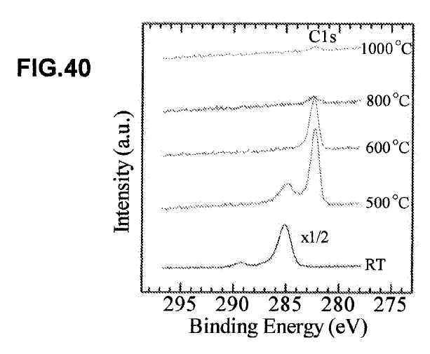

In the planarizing step S41, the Hf (0001) substrate, heat-treated in ultra-high vacuum in the planarizing step S41, was evaluated, using the results of measurement of XPS. FIGS. 38 to 40 show an Hf4f spectrum, a 01s spectrum and a C1s spectrum, respectively. It may be seen that, in the Hf4f spectrum, shown in FIG. 38, the peak of an oxide of Hf, noticed before heat treatment, is decreased as heating is continued, with the peak of metal Hf becoming prominent. It may also be seen that, in the O1s spectrum, shown in FIG. 39, oxygen O is decreased with heating, as in the spectrum for Hf4f, and that, with heating to 1000° C., the surface concentration is decreased appreciably. It may further be seen that, with the C Is spectrum, shown in FIG. 40, the molecular species, adsorbed to the Hf surface before heat treatment, have become desorbed on heating to 500° C. The new peaks appearing in the spectrums for 500° C. and 600° C., shown in FIG. 40, are those for HfC generated by part of an impurity adsorbed to the surface being combined with Hf. When heating is continued further, this HfC peak is decreased and, at 1000° C., the surface concentration of C is decreased appreciably. Thus, it may be seen that, by heat treatment at 800° C. or higher, the surface concentration of oxygen and carbon of an Hf (0001) substrate is decreased appreciably.

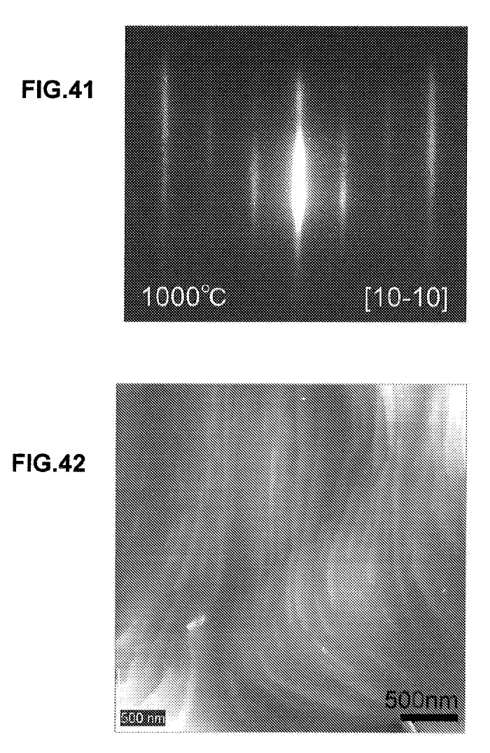

FIGS. 41 and 42 show noticed results of RHEED and AFM for heating at 1000° C. The sharp streaky pattern of the RHEED image indicates that a planar Hf (0001) plane having high crystalline performance has been obtained by mirror surface polishing and heat treatment. The fact that a stepped surface has been produced may also be confirmed from the AFM image.

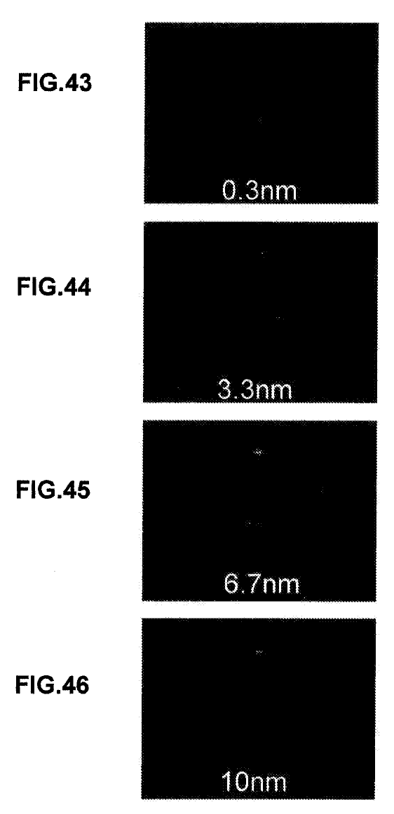

The result that GaN has been allowed to grow on the Hf (0001) substrate, heat-treated and planarized, as described above, is now described. FIGS. 43 to 46 show RHEED patterns, in case GaN with film thicknesses of GaN of 0.3 nm, 3.3 nm, 6.7 nm and 10.0 nm has been allowed to grow at a substrate temperature of 700° C. It has been seen that, if a crystal is allowed to grow at a substrate temperature of 700° C., the crystal pattern is progressively changed into a ring pattern. This indicates that polycrystalline GaN is allowed to grow but no epitaxial growth is taking place.

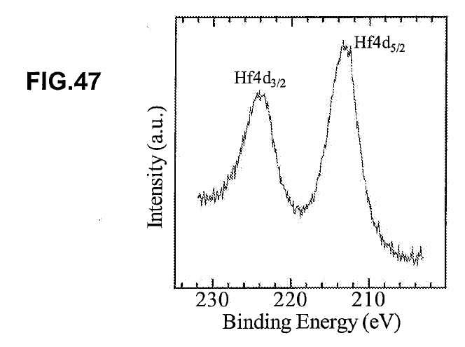

XPS measurement of the polycrystalline GaN surface has testified to a Hf4d peak, thus indicating surface diffusion of Hf, as shown in FIG. 47. Also, GIXR measurement has testified to the thickness of an interfacial reaction layer approximately equal to 4 nm, thus indicating that an interfacial reaction is taking place. From this it is seen that, for growth at 700° C., an interfacial reaction has taken place, because of the high temperature, thus interfering with the crystalline growth.

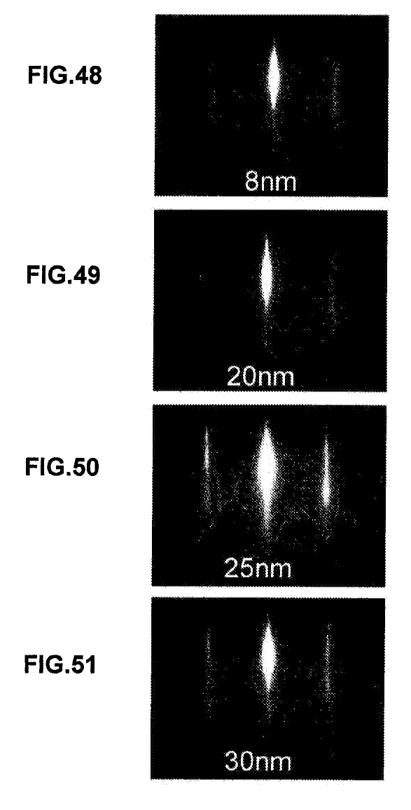

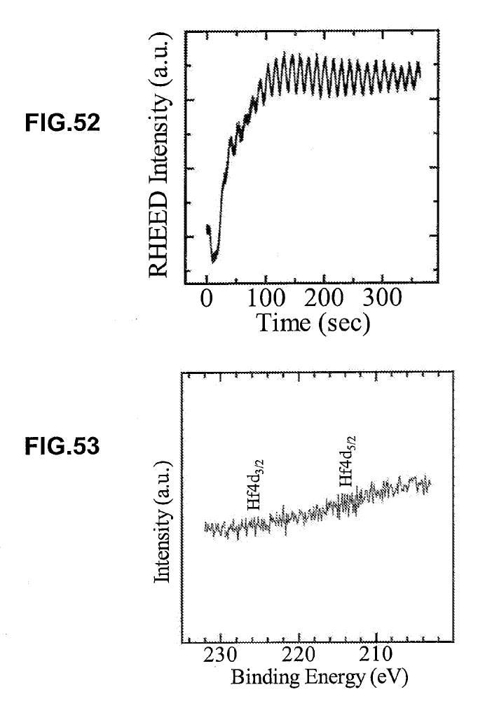

FIGS. 48 to 51 show RHEED patterns for GaN crystals allowed to grow at ambient temperature to film thicknesses of 8 nm, 20 nm, 25 nm and 30 nm, respectively. With crystalline growth at ambient temperature, streaky patterns are presented even if the film thickness is increased, thus testifying to epitaxial growth. On the other hand, since RHEED intensity oscillations are clearly noticed, as shown in FIG. 52, it may be seen that crystal growth proceeds on the layer-by-layer basis. In addition, since spectroscopic ellipsometry indicated that an estimated value of the film thickness of a reaction layer was 10.5 nm, it may be seen that an interfacial reaction takes place at a substrate temperature of 650° C., so that the crystal formed is polycrystalline GaN. On the other hand, if the crystal is allowed to grow at a substrate temperature of 550° C., the RHEED image indicates a streaky pattern. It is therefore preferred for crystal growth to occur in the low-temperature film-forming step S42 at a substrate temperature not lower than 550° C.

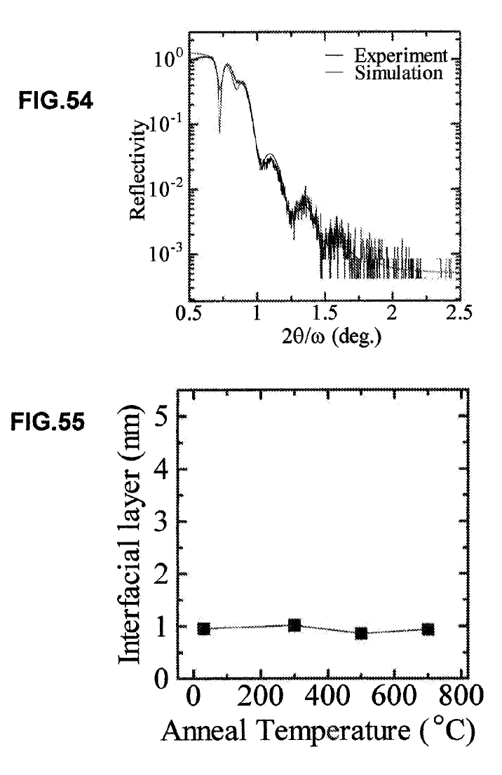

The following description refers to evaluation of a GaN interfacial reaction layer allowed to grow at ambient temperature. FIGS. 53 and 54 show the results of XPS measurement and GIXR measurement, respectively. The results of the XPS measurement indicate no Hf4d peak, thus assuring that no Hf diffusion has taken place. The results of GIXR measurement indicate that the thickness of the interfacial reaction layer may be estimated to be 0.96 nm and hence the interfacial reaction has been suppressed such that a steep interface has been obtained. Since it is possible with the PLD method to decrease the growth temperature to ambient temperature, it has been seen that the interfacial reaction may be suppressed, while the epitaxial growth of GaN at ambient temperature may be realized.

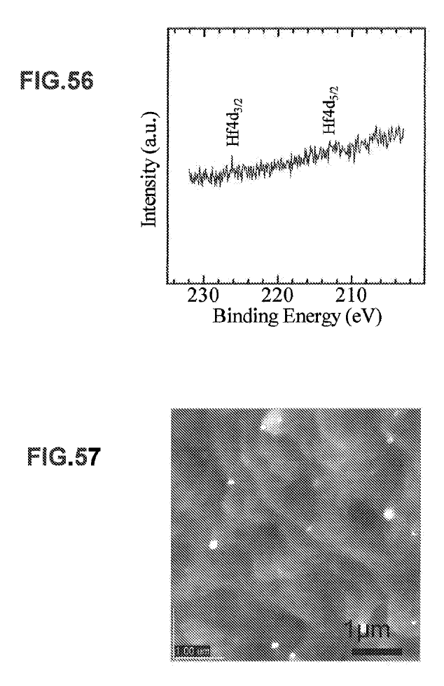

It has been checked whether or not GaN, allowed to grow at ambient temperature, may function as a buffer layer. FIG. 55 shows changes in the film thickness of the GaN thin film against the heat-treatment temperature. FIGS. 56 and 57 show the results of GIXR measurement and AFM observation at 700° C. of the GaN thin film grown at ambient temperature. As may be seen from FIG. 55, the thickness of the surface reaction layer is not seen to be increased even on heating to 700° C. The results of GIXR measurements shown in FIG. 56 indicate that there has occurred no surface diffusion of Hi. The AFM image, shown in FIG. 57, indicates that a stepped structure is kept even at 700° C. Hence, it has been known that GaN, grown at ambient temperature, can operate as a buffer layer, viz. it has been known that, by allowing a buffer layer to grow by epitaxy at a substrate temperature not lower than 550° C. and subsequently allowing GaN to grow at a substrate temperature higher than 550° C., GaN exhibiting satisfactory crystalline properties may be obtained on the Hf (0001) plane.

### Fifth Embodiment

The semiconductor device fabrication process of a fifth embodiment is now described.

### (Constitution of the Semiconductor)

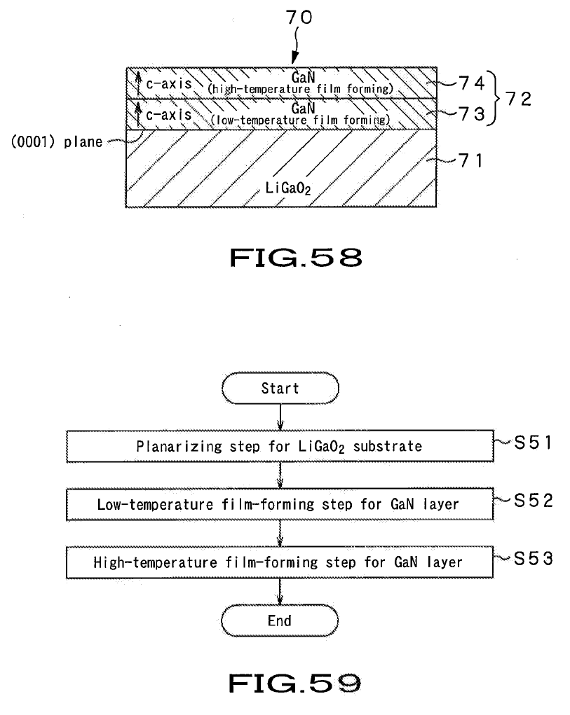

In the fifth embodiment of the fabrication process for the semiconductor device, a nitride semiconductor device 70, having a GaN layer 62 formed on a LiGaO₂ substrate 71, as shown in FIG. 58, is fabricated.

The nitride semiconductor device 70 includes a GaN layer 72, which is oriented so that a c-axis of GaN is perpendicular to the (0001) plane of a LiGaO₂ substrate 71, formed of LiGaO₂. This GaN layer 72 is made up of a first GaN layer 73 and a second GaN layer 74. The first GaN layer 73 is formed by epitaxial growth on the LiGaO₂ substrate 71, at a lower temperature (300° C. or lower), whereas the second GaN layer 74 is formed by epitaxial growth on the first GaN layer 73 at a higher temperature (550° C. or higher).

LiGaO₂ has a rhombic crystalline structure and exhibits extremely small in-plane lattice mismatch of GaN with respect to the C-plane (+1% in the a-axis direction and −0.19% in the b-axis direction). Hence, LiGaO₂ represents a substrate with matched lattice which is efficacious for epitaxial growth of GaN.

Additionally, LiGaO₂ is lacking in center symmetry and has Metal-face polarity and O-face polarity, while it exhibits chemical properties differing significantly from plane to plane. For example, GaN of Ga polarity and GaN of N polarity are allowed to grow on the Metal-face and on the O-face, respectively, allowing the polarity to be controlled easily. In the following, the GaN crystal is allowed to grow on the Metal-face which is more proper as a plane for crystal growth than the O-face, as explained subsequently.

### (Overall Flow)

The respective steps for fabricating the nitride semiconductor device 70 are now described with reference to a flowchart shown in FIG. 59.

As in the first embodiment, the method for fabricating the nitride semiconductor device 70 is divided into a step of planarizing a LiGaO₂ substrate (S51), a step of low-temperature film forming of a GaN layer (S52) and a step of high-temperature film forming of a GaN layer (S53).

### (Planarizing Step S51)

In the planarizing step S51, the LiGaO₂ substrate 71 is sliced so that the substrate surface will become the (0001) plane.

The (0001) plane of the LiGaO₂ substrate 71, thus sliced, is mechanically polished using diamond slurries, for instance. Specifically, the mechanical polishing is carried out using a set of diamond slurries differing in particle size from one diamond slurry to the next. The diamond slurries with progressively smaller particle sizes are used as the mechanical polishing proceeds, until ultimately the diamond slurry of the particle size of approximately 0.5 μm is used to realize mirror surface polishing. Further, colloidal silica is preferably used for polishing until the polished surface has been planarized to the RMS of the surface roughness not larger than 10 Å. The LiGaO₂ substrate 71, thus mechanically polished, is heat-treated, using a high-temperature oven maintained at a temperature of 700° C. or higher and controlled to be in an atmosphere of a hydrogen/helium mixture. This yields the LiGaO₂ substrate 71 planarized to the atomic level.

### (Low-Temperature Film-Forming Step S52)

In a low-temperature film-forming step S52, the first GaN layer 73 is grown by epitaxy, by the PLD (Pulse Laser Deposition) method, on the surface of the LiGaO₂ substrate 71, planarized by the step S51. The PLD method is the same as that of the first embodiment, provided that the substrate placed within the chamber 31 is the LiGaO₂ substrate 71.

The temperature at the time of growth of GaN is set to 300° C. or lower. The initial growth rate at the time of generation of the first GaN layer is set to 10 nm/hour. By so doing, no interfacial reaction takes place at an interface between LiGaO₂ and GaN, so that no interface reaction layer is generated.

### (High-Temperature Film-Forming Step S53)

In the high-temperature film-forming step S53, the second GaN layer 74 is grown epitaxially, by the PLD method, on the first GaN layer 73 formed in the low-temperature film-forming step S52. The temperature at the time of growth of the second GaN layer is set to 550° C. or higher. By so doing, point defects may sufficiently be prevented from being generated at the time of growth of the second GaN layer 74. Also, fine grains generated at the time of film deposition by the low-temperature film-forming step S52 become fused together and disappear at this time. In case the growth temperature is set to 800° C. or higher, GaN is vaporized off so that no crystal may be produced. Meanwhile, in the epitaxial growth of the second GaN layer 74 in the step S53, the physical vapor deposition (PVD), such as MBE, or a MOCVD method, may be used in place of the PLD method.

### (Results of Measurement)

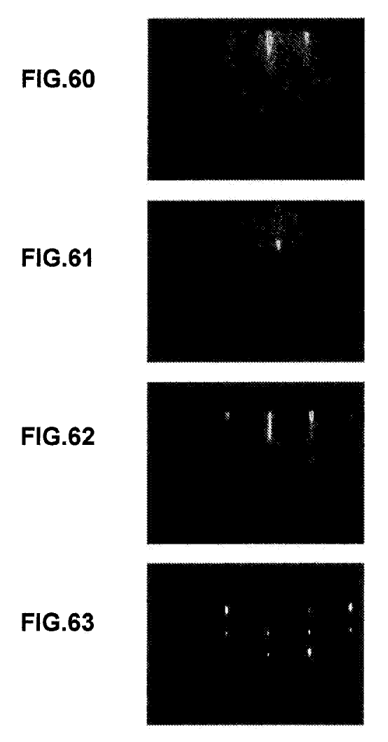

FIGS. 60 and 61 show RHEED images before and after heat treatment on the Metal-face, respectively. FIGS. 62 and 63 show RHEED images before and after heat treatment on the O-face, respectively. Before heat treatment in ultra-high vacuum, the RHEED images, shown in FIGS. 60 and 62, show streaky patterns on both of these faces, indicating flat surfaces. However, the RHEED image on the Metal-face, following heat treatment at 700° C., shown in FIG. 61, shows a sharp streaky pattern, while that on the O-face following heat treatment at 700° C., shown in FIG. 63, shows a spotty pattern. It is seen from this that the Metal-face is higher in thermal resistance than the O-face and may retain surface flatness even after heat treatment.

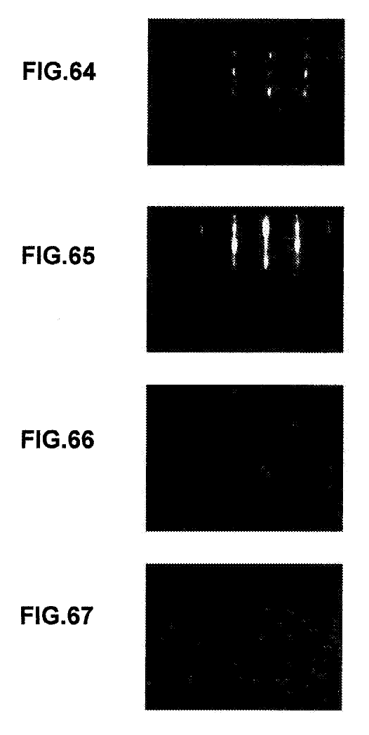

FIGS. 64 to 67 show RHEED images for cases where GaN is allowed to grow on an O-face substrate at 700° C., 500° C., 300° C. and at ambient temperature, respectively. It may be presumed that the RHEED image, shown in FIG. 64, presents a spotty pattern, in case GaN is allowed to grow at 700° C., so that the O-face is roughed and hence GaN has been formed thereon with 3D growth. The RHEED image, shown in FIG. 65, with the substrate temperature of 500° C., also presents a spotty pattern. Hence, it may be seen that GaN has been formed by 3D growth. On the other hand, the RHEED image for the substrate temperature of 300° C. shows a streaky pattern, indicating that the GaN has grown epitaxially. However, the RHEED image for the ambient substrate temperature, shown in FIG. 67, presents a ring pattern, thus not indicating the growth of a single crystal.

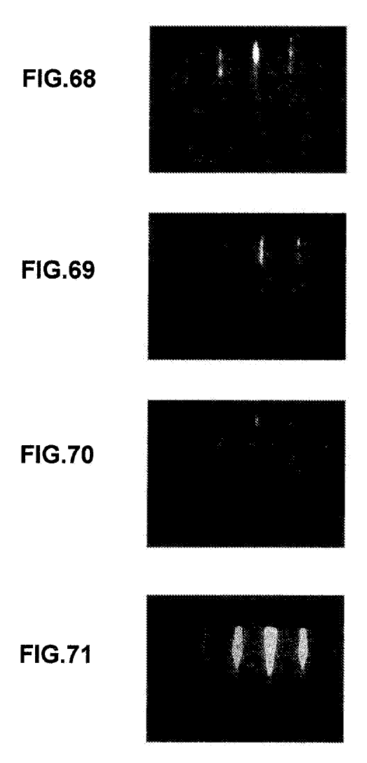

FIGS. 68 to 71 show RHEED images for cases where GaN is allowed to grow on a Metal-face substrate at 700° C., 500° C., 300° C. and at ambient temperature, respectively. For all of these temperature ranges, definite streaky patterns may be noticed, insofar as the growth on the Metal-face substrate is concerned, thus indicating that GaN of optimum quality may be allowed to grow by epitaxy even at ambient temperature.

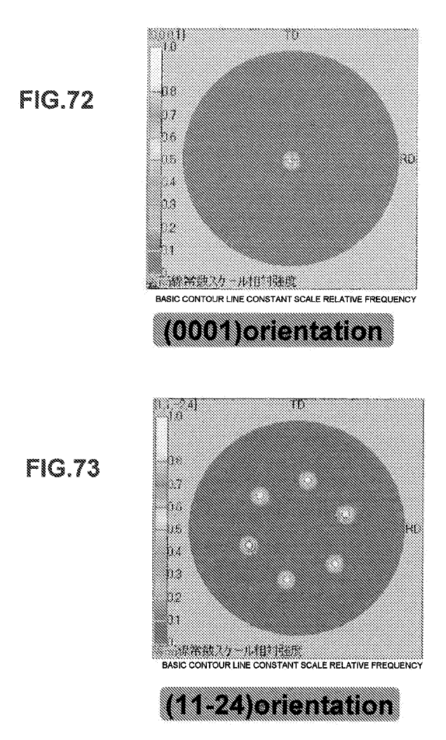

Then, to check the crystalline quality of GaN, grown at ambient temperature on the Metal-face substrate, the crystalline orientation was analyzed by ESBD (Electron Backscatter Diffraction). FIG. 72 depicts a pole figure of the (0001) orientation, and FIG. 73 depicts a pole figure of the (11-24) orientation. It is seen from FIG. 72 that the direction of the c-axis of GaN is orthogonal to the surface, while it is seen from FIG. 73 that definite hexagonal symmetry has been noticed, such that, if crystalline growth occurs at ambient temperature, no 30′-rotational domain is mixed.

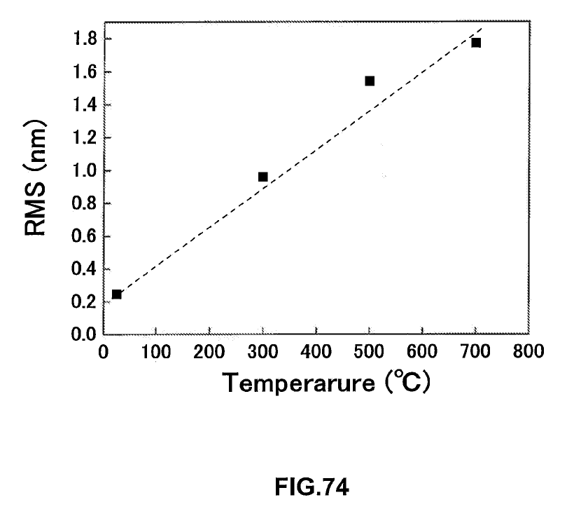

The surface morphology of GaN, allowed to grow on the Metal-face substrate, was checked by AFM. FIG. 74 depicts a graph showing RMS values of surface roughness plotted against the growth temperature. It is seen from this graph that the lower the growth temperature, the more flat becomes the GaN surface, and that satisfactory results of the RMS value of 0.25 nm may be realized for growth at ambient temperature. This is presumably ascribable to the fact that, since the interfacial reaction, otherwise caused due to high temperatures, is suppressed by lowering the growth temperature, crystalline growth has progressed as the substrate surface is maintained in its flat state.

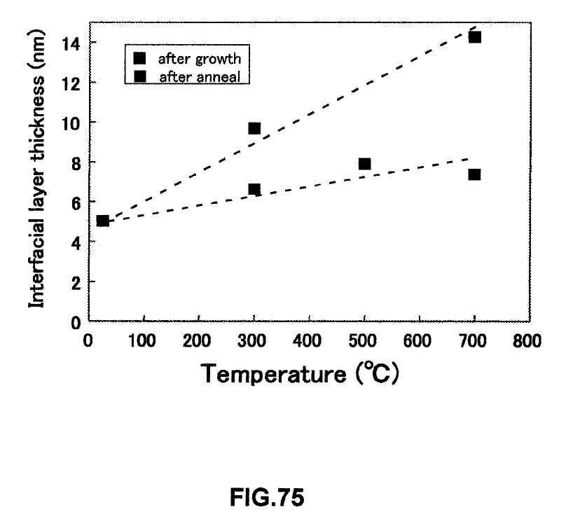

The thickness of the reaction layer, formed on the interface between GaN and the LiGaO₂ substrate, was measured by GIXR. FIG. 75 depicts a graph in which the thickness of the interfacial reaction layer is plotted against the growth temperature. It is seen from this graph that the thickness of the interfacial reaction layer can be decreased by lowering the growth temperature. That is, when the interfacial reaction is suppressed by lowering the growth temperature, the GaN film, formed on the interfacial layer, is improved. It is noted that, when GaN, grown at ambient temperature, is annealed, and measurement is made of the thickness of the interfacial layer, no marked change may be noted for a temperature range from ambient to 700° C. Hence, GaN, grown at ambient temperature, may be used as a buffer layer to be grown in the high-temperature film-forming step S53.

### Sixth Embodiment

A semiconductor fabrication process according to a sixth embodiment is now described.

### (Constitution of the Semiconductor)

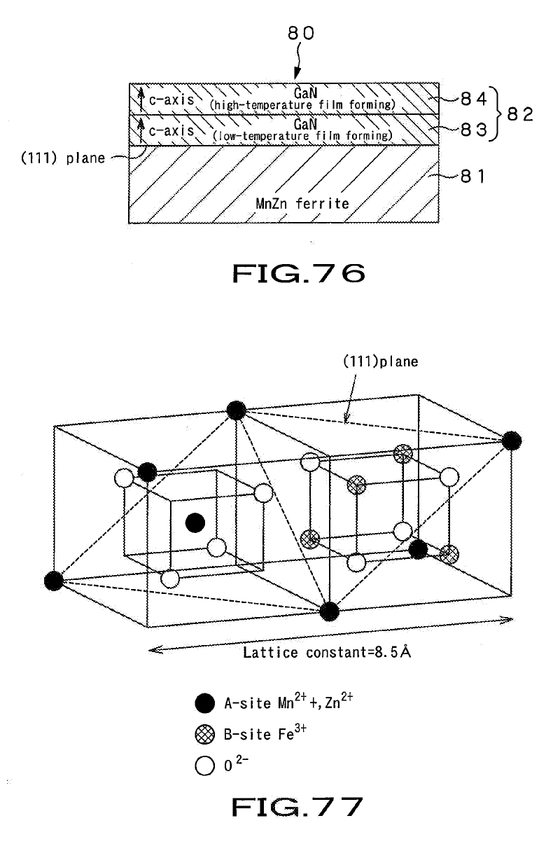

In the sixth embodiment of the fabrication process for the semiconductor device, a nitride semiconductor device 80, having a GaN layer 82 formed on a (Mn, Zn) Fe₂O₄ substrate, as shown in FIG. 76, is fabricated. This (Mn, Zn) Fe₂O₄ substrate is referred to below as MnZn ferrite substrate 81.

The nitride semiconductor device 80 includes a GaN layer 82, which is oriented so that a c-axis of GaN is perpendicular to the (111) plane of the MnZn ferrite substrate 81. This GaN layer 82 is made up of a first GaN layer 83 and a second GaN layer 84. The first GaN layer 82 is formed by epitaxial growth on the MnZn ferrite substrate 81, at ambient temperature, whereas the second GaN layer 74 is formed by epitaxial growth on the first GaN layer 83 at a higher temperature (550° C. or higher).

The MnZn ferrite has a spinel structure, shown in FIG. 77, with the lattice mismatch thereof to GaN with respect to the (111) plane being small and being 6.1%. Hence, the MnZn ferrite is a lattice-matched substrate effective to cause epitaxial growth of GaN. This MnZn ferrite exhibits high electrical conductivity and hence may be used with advantage for device fabricating processes.

### (Overall Flow)

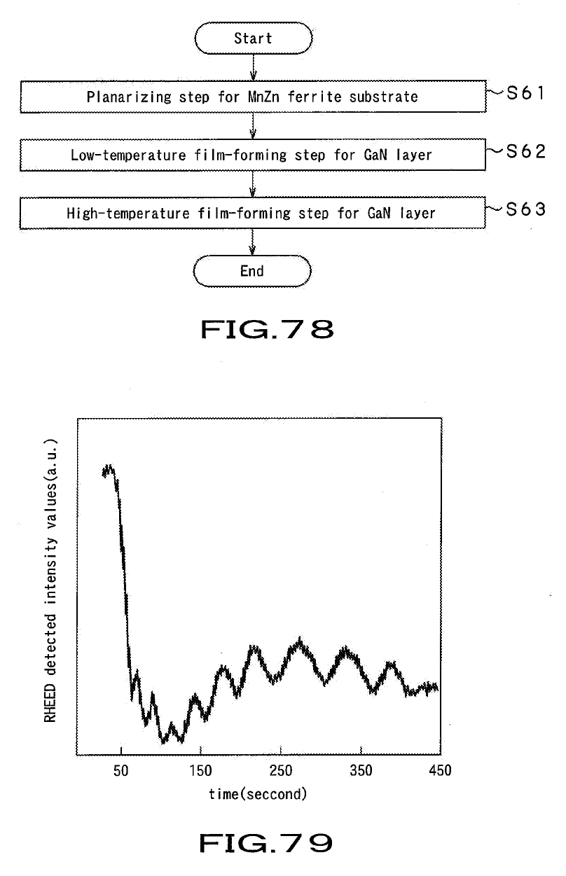

The respective steps for fabricating the nitride semiconductor device 80 are now described with reference to a flowchart shown in FIG. 78.

As in the first embodiment, the method for fabricating the nitride semiconductor device 80 is divided into a step of planarizing a MnZn ferrite substrate 81 (S61), a step of low-temperature film forming of a GaN layer (S62) and a step of high-temperature film forming of a GaN layer (S63).

### (Planarizing Step S61)

In the planarizing step S61, the MnZn ferrite substrate 81 is sliced so that the substrate surface will become the (111) plane.

The (111) plane of the MnZn ferrite substrate 81, thus sliced, is mechanically polished using diamond slurries, for instance. Specifically, the mechanical polishing is carried out using a set of diamond slurries differing in particle size from one diamond slurry to the next. The diamond slurries with progressively smaller particle sizes are used as the mechanical polishing proceeds, until ultimately the diamond slurry of the particle size of approximately 0.5 μm is used to realize mirror surface polishing. Further, colloidal silica is preferably used for polishing until the polished surface has been planarized to the RMS value of the surface roughness not larger than 10 Å. The MnZn ferrite substrate is ultrasonically rinsed in alcohol and subsequently heat-treated in ultra-vacuum at 800° C. for 15 minutes. This yields the MnZn ferrite substrate 81 planarized to the atomic level.

### (Low-Temperature Film-Forming Step S62)

In a low-temperature film-forming step S62, the first GaN layer 83 is grown by epitaxy, by the PLD (Pulse Laser Deposition) method, on the surface of the MnZn ferrite substrate 81, planarized by the step S61. The PLD method is the same as that of the first embodiment, provided that the substrate placed within the chamber 31 is the MnZn ferrite substrate 81.

The temperature at the time of growth of GaN is set to 300° C. or lower. The initial growth rate at the time of generation of the first GaN layer is set to 10 nm/hour. By so doing, no interfacial reaction takes place at an interface between MnZn ferrite and GaN, so that no interface reaction layer is generated.

### (High-Temperature Film-Forming Step S63)

In the high-temperature film-forming step S63, the second GaN layer 84 is grown epitaxially, by the PLD method, on the first GaN layer 83 formed in the low-temperature film-forming step S62. The temperature at the time of growth of the second GaN layer is set to 550° C. or higher. By so doing, point defects may sufficiently be prevented from being generated at the time of growth of the second GaN layer 84. Also, fine grains generated at the time of film deposition by the low-temperature film-forming step S62 become fused together and disappear at this time. In case the growth temperature is set to 800° C. or higher, GaN is vaporized off so that no crystal may be produced. Meanwhile, in the epitaxial growth of the second GaN layer 84 in the step S63, the physical vapor deposition (PVD), such as MBE, or a MOCVD method, may be used in place of the PLD method.

### (Results of Measurement)

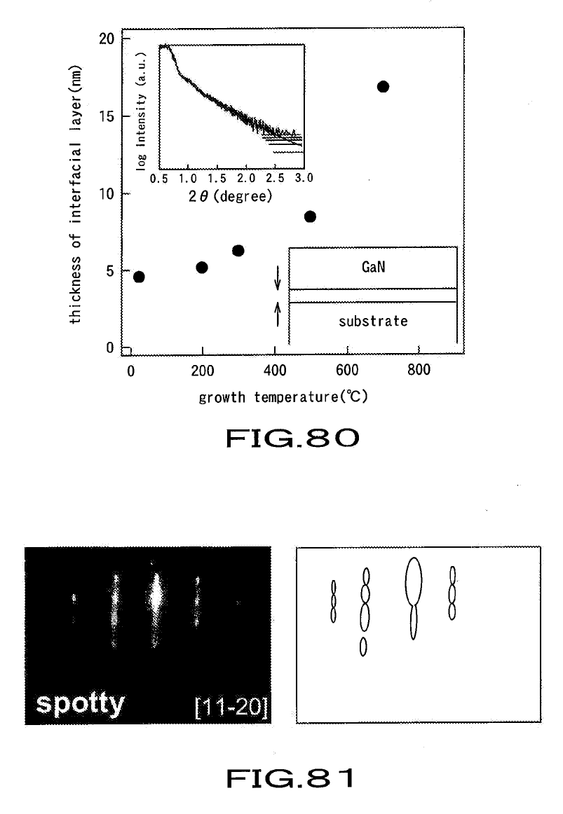

FIG. 79 shows the results of visual in-situ RHEED check in the course of growth at ambient temperature of a GaN thin film. At an initial growth stage, RHEED oscillations, indicating layer-by-layer growth of GaN, was noticed. Also, since transition to a spotty pattern, indicating 3D growth, takes place when the film thickness of the GaN thin film increases, it has become clear that, in the course of growth of a GaN film on the MnZn ferrite, transition takes place from the 2D growth to the 3D growth. This is presumably ascribable to storage of the distortion energy in the GaN thin film.

The thickness of the interfacial layer was also measured by GIXR (Grazing Incidence X-Ray Reflectometry), as shown in FIG. 80.

As a result, it has become clear that the thickness of the interfacial layer decreases as the growth temperature is lowered, and that surface steepness is improved by decreasing the growth temperature.

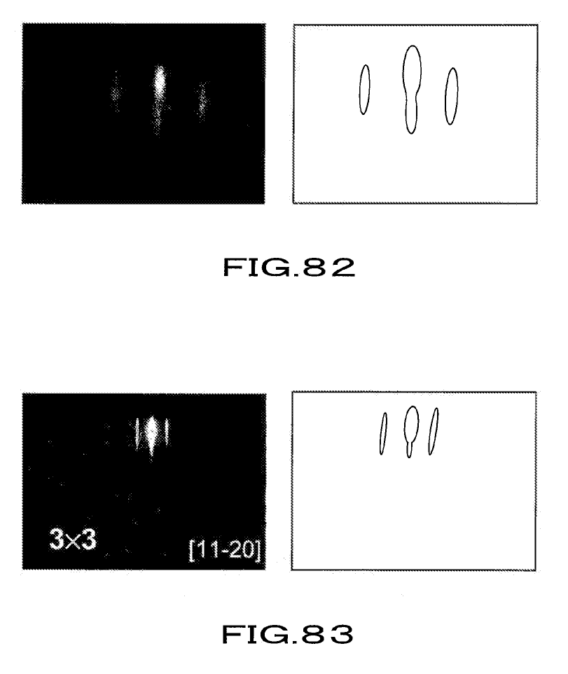

FIG. 81 shows a RHEED image, obtained on growth of GaN at 700° C., and FIG. 82 shows a RHEED image, obtained on growth of GaN at ambient temperature. FIG. 83 shows a RHEED image, obtained on growth of GaN at ambient temperature and subsequently at 700° C. Meanwhile, the left and right sides of FIGS. 81 to 83 depict a view derived from a photo and a schematic view thereof, respectively.

Referring to FIG. 82, GaN, allowed to grow at ambient temperature, exhibits RHEED oscillations, indicating layer-by-layer growth. However, if GaN is allowed to grow at a temperature of 700° C., as shown in FIG. 81, a spot-like pattern, indicating poor crystalline properties, is displayed. However, if GaN is allowed to grow at ambient temperature, and subsequently at 700° C., not the spot-like pattern, but a streaky pattern is displayed, thus testifying to growth of the GaN thin film showing good crystalline performance.

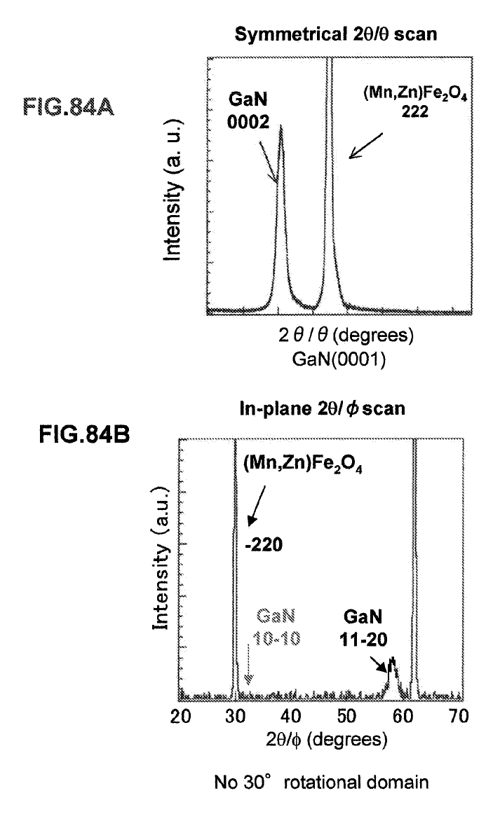

FIGS. 84(A) and 84(B) depict XRD curves of a GaN film, allowed to grow at ambient temperature to a film thickness of 100 nm. From the results of the XRD measurement, the GaN thin film, allowed to grow at ambient temperature, is of a single domain, there being no 30′-rotation domain mixed in the GaN thin film.

It is seen from above that crystalline growth at ambient temperature suppresses an interfacial reaction between the substrate and the nitride to allow epitaxial growth of GaN of high quality on the MnZn ferrite substrate.

### Seventh Embodiment

A semiconductor fabrication process according to a seventh embodiment is now described.

### (Constitution of the Semiconductor)

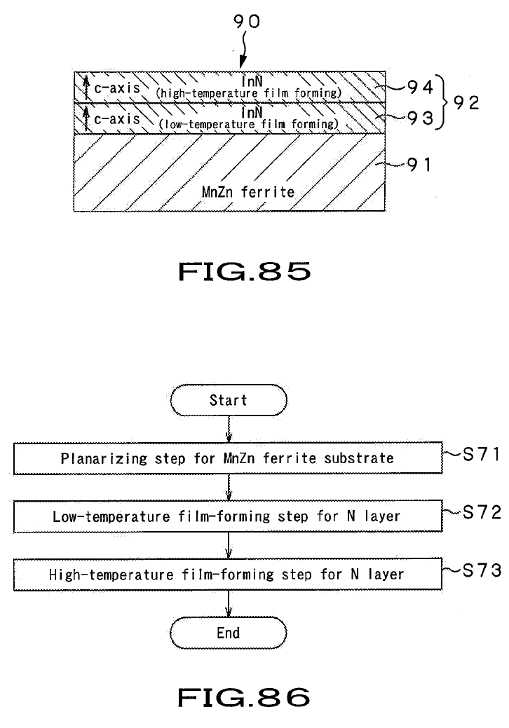

In the seventh embodiment of the fabrication process for the semiconductor device, a nitride semiconductor device 90, having an InN layer 92 formed on a (Mn, Zn) Fe₂O₄ substrate, as shown in FIG. 85, is fabricated. This (Mn, Zn) Fe₂O₄ substrate is referred to below as MnZn ferrite substrate 91.

The nitride semiconductor device 90 includes an InN layer 92, which is oriented so that a c-axis of InN is perpendicular to the (111) plane of the MnZn ferrite substrate 91. This InN layer 92 is made up of a first InN layer 93 and a second InN layer 94. The first InN layer 93 is formed by epitaxial growth on the MnZn ferrite substrate 91, at ambient temperature, whereas the second InN layer 94 is formed by epitaxial growth on the first InN layer 93 at a higher temperature (500° C. to 550° C.).

The MnZn ferrite has a spinel structure, shown in FIG. 77, with the lattice mismatch thereof to InN with respect to the (111) plane being 17.7%. However, the MnZn ferrite gives a lattice-matched substrate effective to cause epitaxial growth of InN, because the lattice mismatch decreases to 2.0% due to 30°-rotation, as will be described. This MnZn ferrite exhibits high electrical conductivity and hence may be used with advantage for device fabricating processes.

### (Overall Flow)

The respective steps for fabricating the nitride semiconductor device 90 are now described with reference to a flowchart shown in FIG. 86.

As in the first embodiment, the method for fabricating the nitride semiconductor device 90 is divided into a step of planarizing a MnZn ferrite substrate (S71), a step of low-temperature film forming of an InN layer (S72) and a step of high-temperature film forming of an InN layer (S73).

### (Planarizing Step S71)

In the planarizing step S71, the MnZn ferrite substrate 91 is sliced so that the substrate surface will become the (111) plane.

The (111) plane of the MnZn ferrite substrate, thus sliced, is mechanically polished using diamond slurries, for instance. Specifically, the mechanical polishing is carried out using a set of diamond slurries differing in particle size from one diamond slurry to the next. The diamond slurries with progressively smaller particle sizes are used as the mechanical polishing proceeds, until ultimately the diamond slurry of the particle size of approximately 0.5 μm is used to realize mirror surface polishing. Further, colloidal silica is preferably used for polishing until the polished surface has been planarized to the RMS value of the surface roughness not larger than 10 Å. The MnZn ferrite substrate is ultrasonically rinsed in alcohol and subsequently heat-treated in ultra-vacuum at 800° C. for 15 minutes. This yields the MnZn ferrite substrate 91 planarized to the atomic level.

### (Low-Temperature Film-Forming Step S72)

In the low-temperature film-forming step S72, the first InN layer 93 is grown by epitaxy, by the PLD (Pulse Laser Deposition) method, on the surface of the MnZn ferrite substrate 91, planarized by the step S71. The PLD method is the same as that of the first embodiment, provided that the substrate placed within the chamber 31 is the MnZn ferrite substrate 91.

The temperature at the time of growth of InN is set to 300° C. or lower. The initial growth rate at the time of generation of the first InN layer is set to 10 nm/hour. By so doing, no interfacial reaction takes place at an interface between MnZn ferrite and InN, so that no interface reaction layer is generated.

### (High-Temperature Film-Forming Step S73)

In the high-temperature film-forming step S73, the second InN layer 94 is grown epitaxially, by the PLD method, on the first InN layer 93 formed in the low-temperature film-forming step S72. The temperature at the time of growth of the second InN layer is set to 550° C. or higher. By so doing, point defects may sufficiently be prevented from being generated at the time of growth of the second InN layer 94. Meanwhile, in the epitaxial growth of the second InN layer 94 in the step S73, the physical vapor deposition (PVD), such as MBE, or a MOCVD method, may be used in place of the PLD method.

### (Results of Measurement)

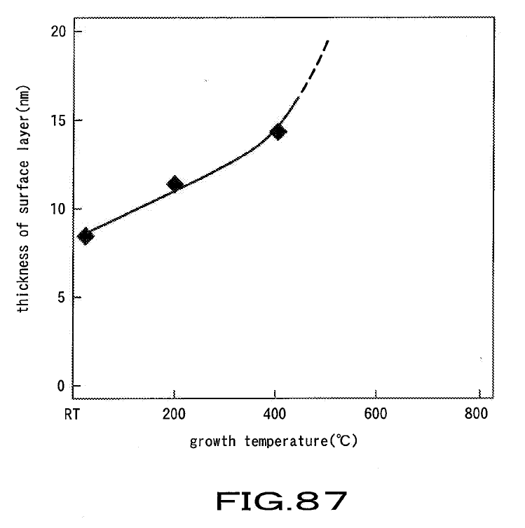

FIG. 87 shows results of measurement of the thickness of the interfacial layer against the growth temperature by GIXR (Grazing Incidence X-Ray Reflectometry). From the results of measurement, it has become clear that the thickness of the interfacial layer decreases as the growth temperature is lowered, and that surface steepness is improved by decreasing the growth temperature.

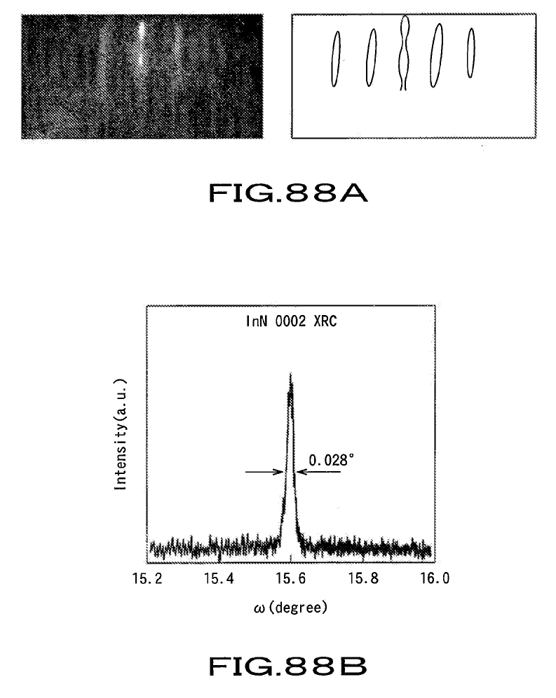

FIGS. 88 to 91 show RHEED images and the results of measurement of XRD in case InN was allowed to grow by epitaxy at ambient temperature, 150° C., 400° C. and 550° C., respectively. FIGS. 92 to 95 show the results of check by the atomic force microscope in case GaN has been grown by epitaxy at ambient temperature, 150° C., 400° C. and 550° C., respectively. Meanwhile, the left and right sides of FIGS. 92 to 95 depict views derived from photos and schematic views thereof, respectively.

Referring to FIG. 88(A), in case InN is grown at ambient temperature, the RHEED image presents a streaky pattern. From FIG. 88(B), the ½ value (half-width) of the peak of X-ray intensity for the 0002 diffraction is 0.028°, indicating that an InN layer with a flat surface has been formed. This may also be confirmed from a stepped surface showing the results of observation of FIG. 92.

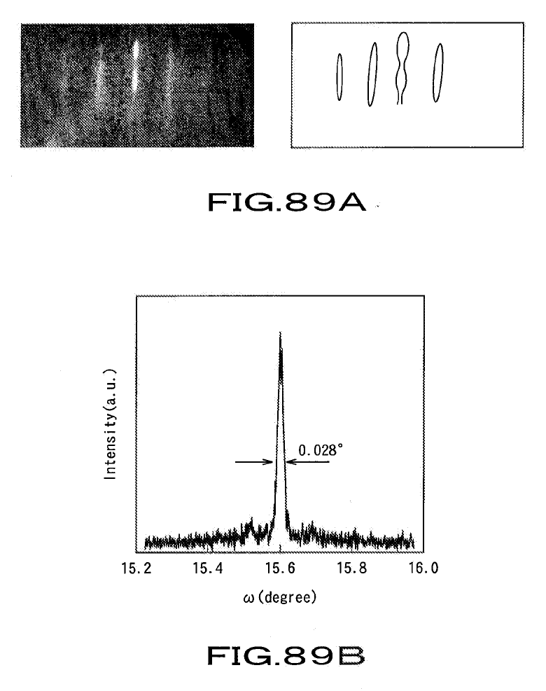

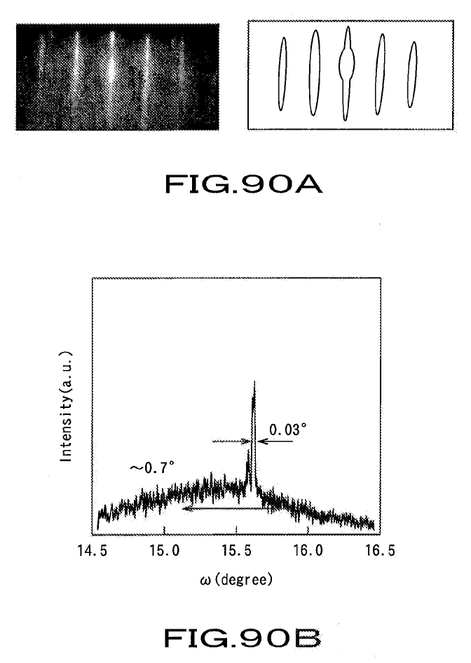

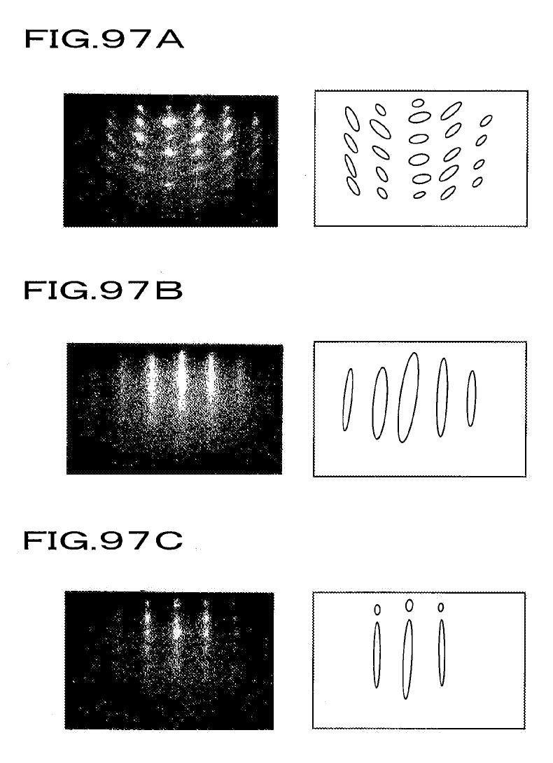

Referring to FIG. 89(A), in case InN is grown at 150° C., the RHEED image presents a streaky pattern. From FIG. 89(B), the ½ value (half-value width) is 0.028°, indicating that an InN layer with a flat surface has been formed. This may also be confirmed from a stepped surface showing the results of observation of FIG. 93.

Referring to FIG. 90(A), in case InN is grown at 400° C., the RHEED image presents a spotty pattern. From FIG. 90(B), the ½ value (half-value width) is 0.03°. On the other hand, the observed surface shown in FIG. 94 is not stepped, thus testifying to the deteriorated crystalline properties. This may be ascribable to the fact that, with crystal growth at 400° C., as in the measured results of XRD, shown in FIG. 96, the (11-20) plane of InN becomes parallel to the (01-1) plane of MnZn ferrite, with the lattice mismatch amounting to 18%. Conversely, with crystal growth at ambient temperature, the (11-20) plane of InN becomes parallel to the (11-2) plane of MnZn ferrite, with the lattice mismatch amounting to 2.0%. This presumably accounts for the growth of a high-quality crystal.

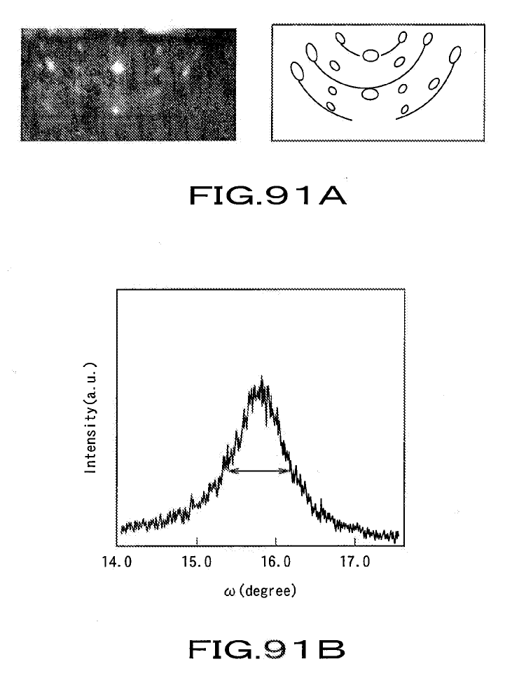

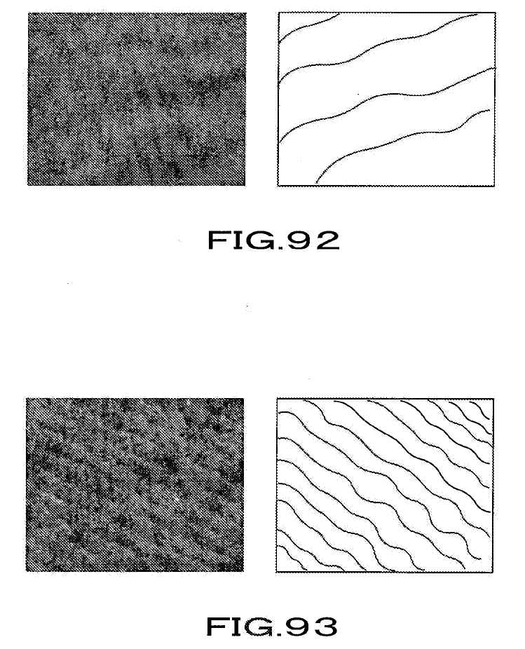

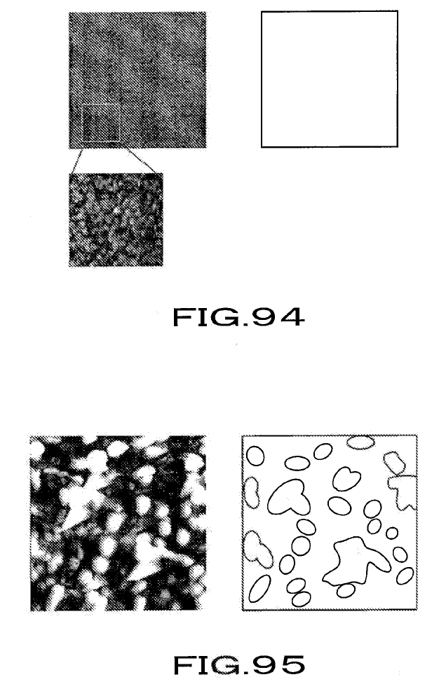

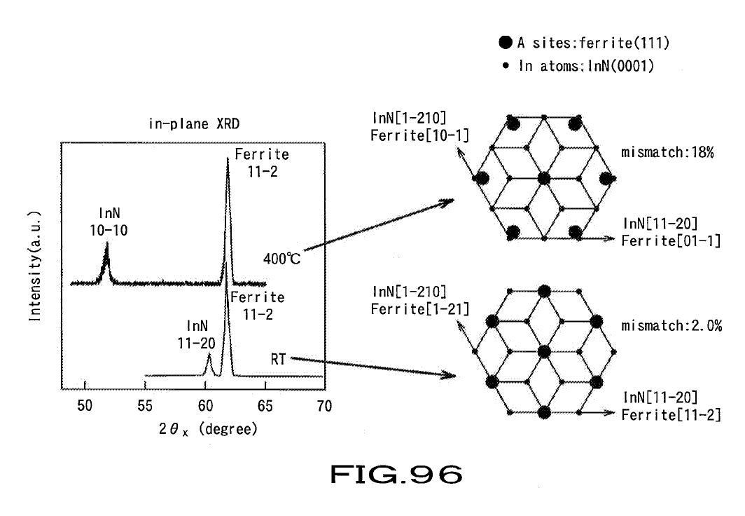

In case InN is allowed to grow at 550° C., the RHEED image shows a ring pattern, as shown in FIG. 91, with the half-value width being 0.73°, indicating that an InN layer of high quality has not been formed. This may also be confirmed from the fact that, in the surface state shown in FIG. 95, the RMS value of the surface roughness amounts to 41 nm.

FIG. 97A, 97B and 97C depict RHEED images for a case where the InN layer is grown at 500 to 550° C., a case where the InN layer is grown at ambient temperature and a case where the InN layer is grown at ambient temperature and subsequently at 500 to 550° C., respectively. Meanwhile, the left and right sides of FIG. 97 depict views derived from photos and schematic views thereof, respectively.

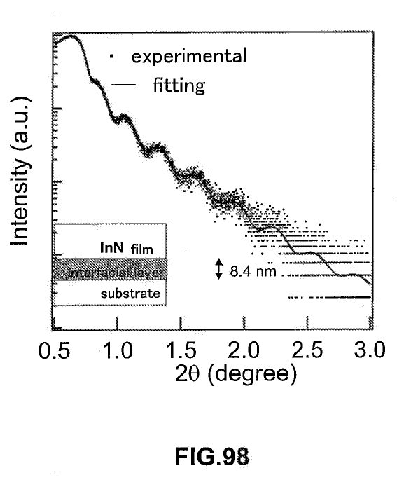

In case the InN layer is grown at 500 to 550° C., a ring pattern is obtained, as shown in FIG. 97A. GIXR measurements have indicated that a reaction layer not less than 10 nm is produced at an interface between MnZn ferrite and the InN layer, as shown in FIG. 98. If the InN layer is grown at ambient temperature, a streaky pattern shown in FIG. 97B is obtained, indicating suppression of generation of the reaction layer and also indicating growth of a single crystal. On the other hand, if an InN layer is grown at ambient temperature and subsequently at 500 to 550° C., the pattern shown in FIG. 97C is obtained. Thus, it has been shown that, by using the InN layer, grown at ambient temperature, as a buffer layer, a single crystal of high quality may be obtained even at high temperatures. The in-plane orientation relationship at this time is such that the (11-20) plane of InN is parallel to the (11-2) plane of MnZn ferrite.

Thus, it has been shown that crystal growth at ambient temperature suppresses an interfacial reaction between the substrate and the nitride to help generate heteroepitaxial growth of high-quality InN on the MnZn substrate.

On the other hand, AlN with the lattice constant a being such that a=3.110 has a lattice mismatch to MnZn ferrite which is as low as 3.4%. Hence, AlN may be grown on the MnZn ferrite substrate.

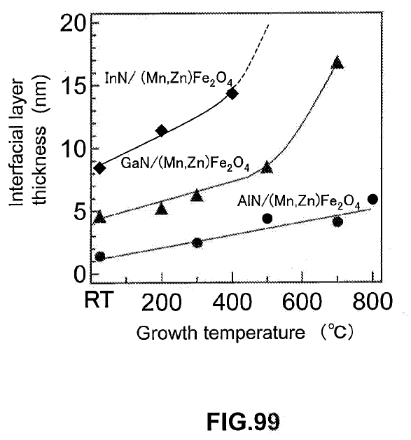

FIG. 99 indicates measured results of the thickness of the interfacial reaction layer against the growth temperature in case GaN, InN and AlN are allowed to grow on the MnZn ferrite substrate. From these measured results, it is seen that the interfacial reaction may be suppressed by decreasing the growth temperature.

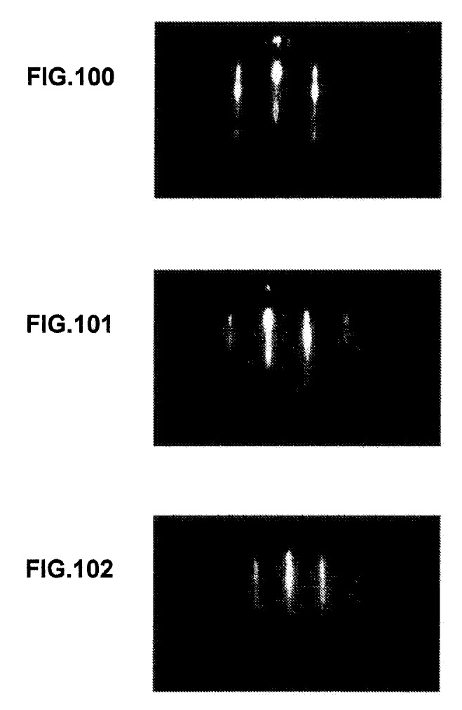

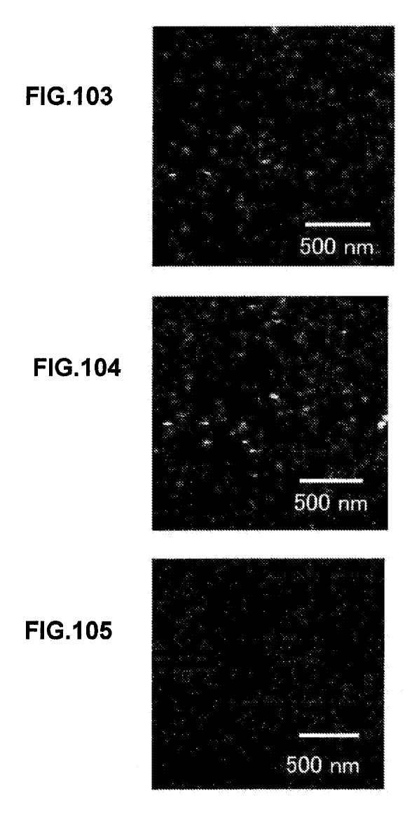

FIGS. 100 to 102 depict RHEED images of AlN grown at 750° C., 500° C. and at ambient temperature, respectively. FIGS. 103 to 105 depict the results of observation of the AlN surfaces grown at 750° C., 500° C. and at ambient temperature, respectively. In case of growth at 770° C., a RHEED image exhibiting a spotty pattern as shown in FIG. 100 is obtained and, since the AFM image, shown in FIG. 103, presents a roughed surface, it may be seen that AlN has undergone 3D growth. In case of growth at 550° C., a RHEED image exhibiting a spotty pattern as shown in FIG. 101 is obtained and, since the AFM image, shown in FIG. 104, presents a roughed surface, it may be seen that AlN has undergone 3D growth. Conversely, with growth at ambient temperature, a RHEED image, showing a streaky pattern, as shown in FIG. 103, is obtained and, since the AFM image presents a roughed surface, as shown in FIG. 105, it may be seen that AlN has undergone 2D growth.

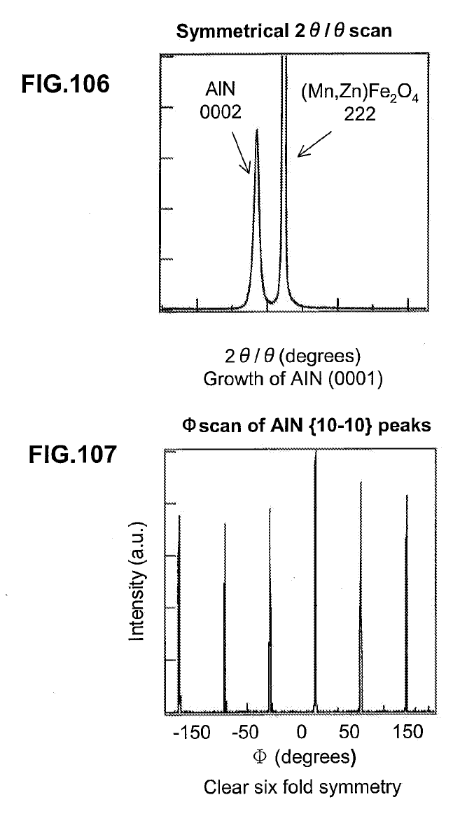

FIGS. 106 and 107 depict XRD curves for AlN allowed to grow at ambient temperature. From measured results of XRD, AlN, grown at ambient temperature, was found to be of a single domain. Also, from FIG. 107, definite hexagonal symmetry could be confirmed.

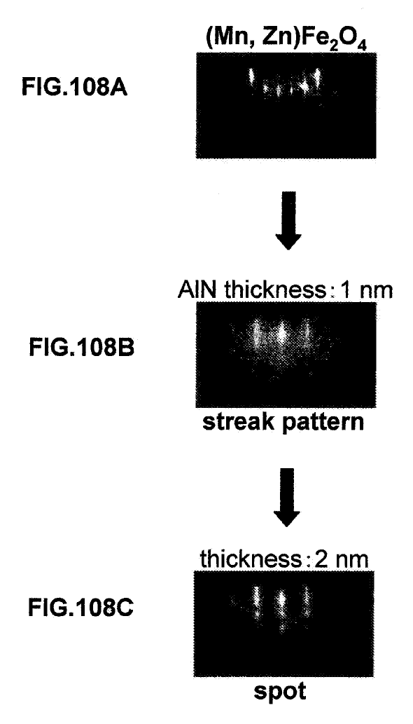

FIG. 108 shows the results of observation of initial growth of AlN. When AlN was allowed to grow to a thickness of 1 nm, the RHEED image of the MnZn ferrite substrate, shown in FIG. 108A, was changed to a sharp streaky pattern, as shown in FIG. 108B. When AlN was allowed to grow further to a thickness of 2 nm, the RHEED image changed to a spotty pattern, as shown in FIG. 108C.

That is, it can be seen that the growth mode is changed in the stage of the initial growth.

### Eighth Embodiment

A semiconductor fabrication process according to an eighth embodiment is now described.

### (Constitution of the Semiconductor)

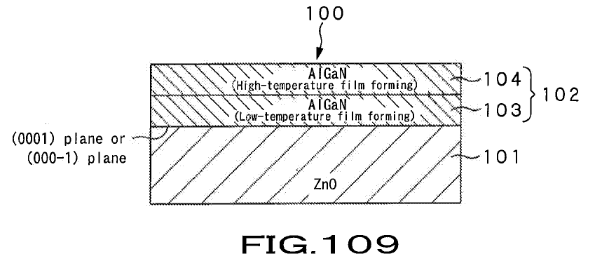

In the eighth embodiment of the fabrication process for the semiconductor device, a nitride semiconductor device 100, having an AlGaN layer 102 formed on a Zn substrate 101, as shown in FIG. 109, is prepared.

The nitride semiconductor device 100 includes an AnGaN layer 102, which is oriented so that a c-axis of AlGaN is perpendicular to the (0001) plane or the (000-1) plane of the Zn substrate 101. This AlGaN layer 102 is made up of a first AlGaN layer 103 and a second AlGaN layer 104. The first AlGaN layer 103 is formed by epitaxial growth on the Zn substrate 101 at a lower temperature (300° C. or less), whereas the second AlGaN layer 104 is formed by epitaxial growth on the first AlGaN layer 103 at a higher temperature (550° C. or higher).

ZnO making up the ZnO substrate 101 has a crystalline structure of the wurtzite type, with the lattice constant a being such that a=3.252 Å, with the forbidden bandwidth being 3.2 eV and with the binding energy of the excitons being 60 meV.

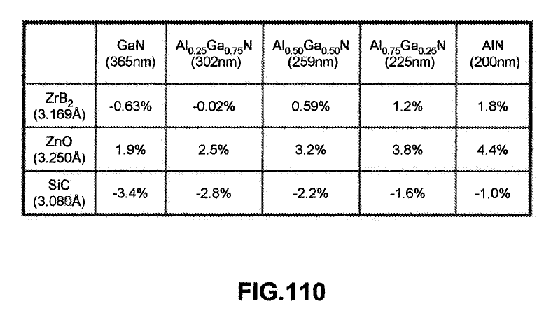

AlGaN, layered on the Zn substrate 101, and which makes up the AlGaN layer 102, has a lattice mismatch not greater than 5%, although the mismatch is varied with the contents of Al and Ga, as shown in FIG. 110.

The lattice constants of ZnO and AlGaN, having the above crystalline structure, are approximately equal to each other, and hence the lattice mismatch may be reduced to a smallest value possible.

### (Overall Flow)

The respective steps for fabricating the nitride semiconductor device 100 are now described in detail.

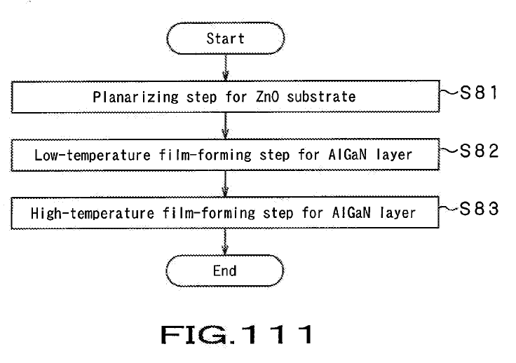

In fabricating the nitride semiconductor device 100, a step of planarizing a ZnO ferrite substrate (S81), a step of low-temperature film forming of an AlGaN layer (S82) and a step of high-temperature film forming of an AlGaN layer (S83) are carried out in this order, as shown in FIG. 111.

### (Planarizing Step S81)

In the planarizing step, the same processing as that of the planarizing step of the step S11 in the first embodiment described above.

### (Low-Temperature Film-Forming Step S82)

Then, in the low-temperature film-forming step S82, the first AlGaN layer 104 is formed by epitaxial growth on the (0001) plane or on the (000-1) plane of the Zn substrate 101 in accordance with the PLD method.

The temperature at growth of AlGaN is set to 300° C. or less. Meanwhile, the PLD method is the same as the method of the low-temperature film-forming step S12 of the first embodiment.

### (High-Temperature Film-Forming Step S83)

Then, in the high-temperature film-forming step S83, a second AlGaN layer 45 is formed by epitaxial growth on the first AlGaN layer 104 formed in the low-temperature film-forming step S82. The temperature at the time of growth of AlGaN is set to 550° C. or higher.

The temperature at the time of growth of AlGaN is set to 550° C. or higher in the high-temperature film-forming step S83 because a temperature sufficient to suppress point defect from being generated must be set at the time of epitaxial growth of the GaN layer. The fine grains generated on low-temperature film deposition in the low-temperature film-forming step S82 become fused together and extinct.

### (Results of Measurement)

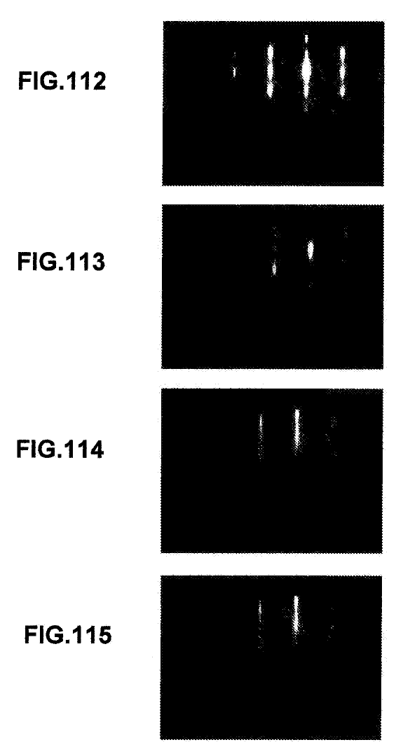

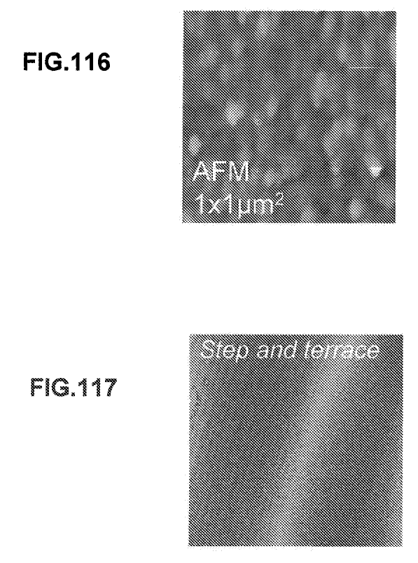

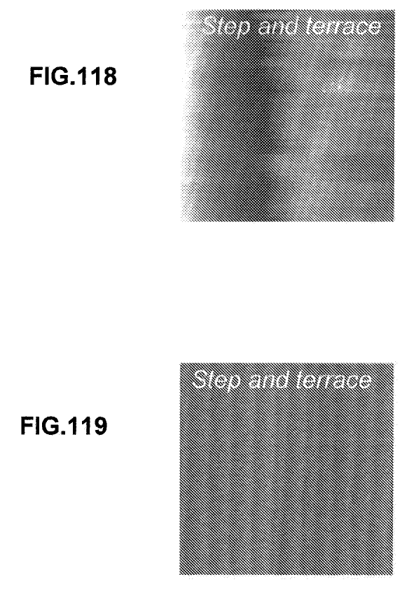

FIGS. 112 to 115 show RHEED images of AlGaN allowed to grow at 600° C., 400° C., 200° C. and at ambient temperature, respectively. FIGS. 116 to 119 show AFM images of AlGaN grown at 600° C., 400° C., 200° C. and at ambient temperature, respectively.

In these results of observation, it is seen that the RHEED image, shown in FIG. 112, indicates a spotty pattern, and that, as may be seen from an AFM image, shown in FIG. 116, AlGaN, allowed to grow at 600° C., is formed by 3D growth characterized by inferior crystalline performance. On the other hand, since the RHEED images, shown in FIGS. 113 to 115 indicate a streaky pattern, and the AFM images, shown in FIGS. 116 to 119, exhibit the step-and-terrace structure, it is seen that optimum epitaxial growth is taking place for a temperature range from ambient to 400° C.

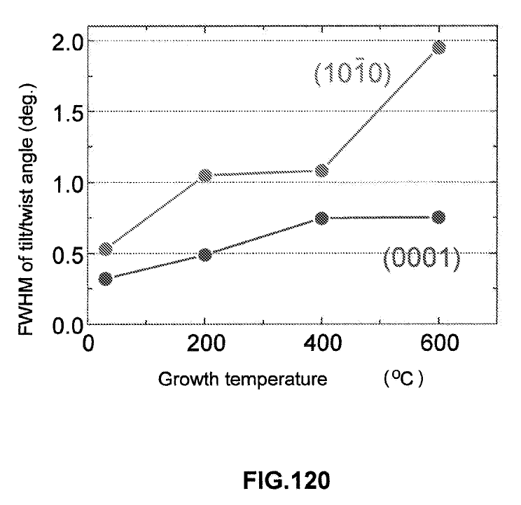

FIG. 120 shows results of EBSD measurement against the growth temperature of AlGaN grown to a film thickness of approximately 30 nm. It is seen from these results that the crystalline performance at the very beginning phase of crystal growth may be improved by using the low growth temperature. That is, an ultra-thin film may be obtained by crystalline growth at ambient temperature.

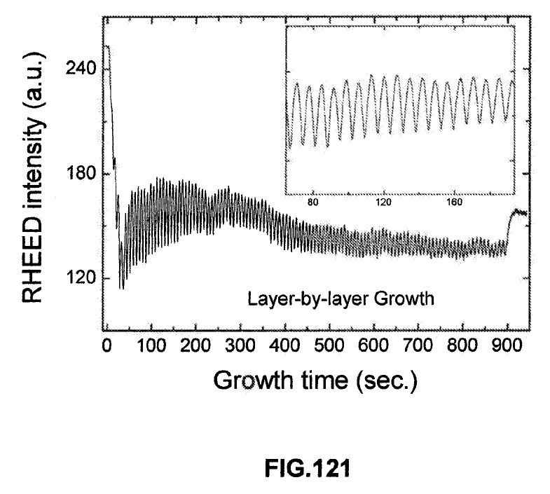

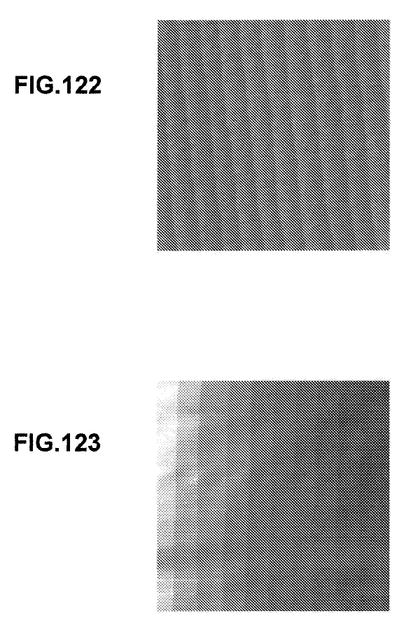

FIG. 121 depicts a graph showing oscillations of the RHEED intensity for growth at ambient temperature of AlGaN. The definite intensity profile testifies to layer-by-layer growth at ambient temperature. Also, from the AFM image of ZnO following heat treatment, shown in FIG. 122, and from the AFM image of AlGaN, grown at ambient temperature, shown in FIG. 123, the film presents a flat AlGaN surface that reflects the state of the substrate surface.

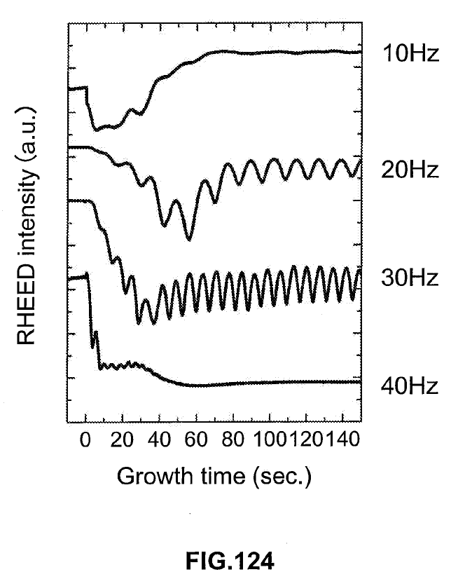

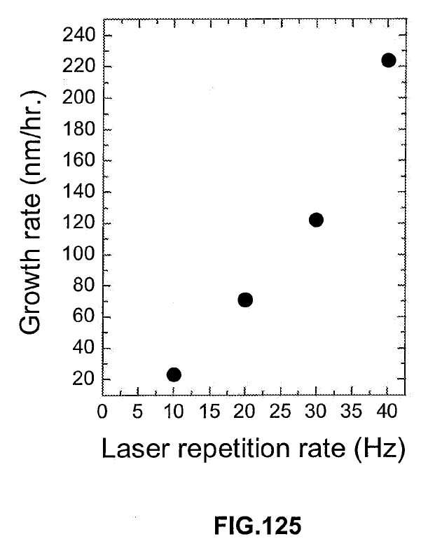

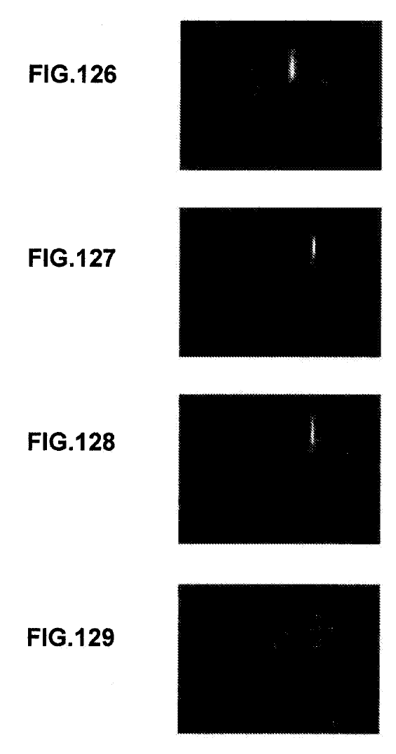

FIG. 124 depicts RHEED intensity oscillations for KrF excimer laser repetition rates of 10 Hz, 20 Hz, 30 Hz and 40 Hz for crystalline growth at ambient temperature. FIG. 125 depicts the growth rate for KrF excimer laser repetition rates for crystalline growth at ambient temperature. FIGS. 126 to 129 depict RHEED images at 10 Hz, 20 Hz, 30 Hz and 40 Hz, respectively. It is seen from these results that the growth rate strongly depends on the ablation frequency. Also, from the RHEED images, shown in FIGS. 126 to 129, epitaxial growth may take place at ambient temperature by slowing down the growth rate.

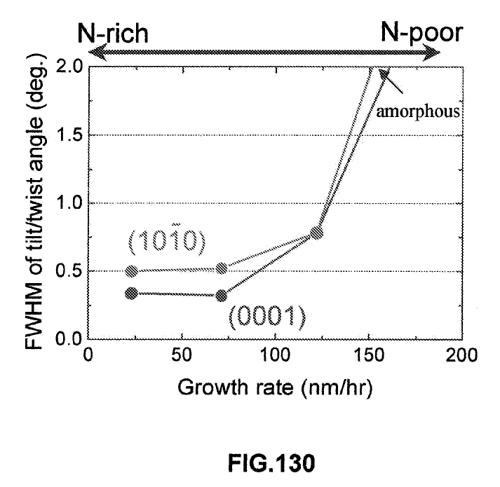

FIG. 130 shows the results of EBSD measurement against the growth rate of AlGaN allowed to grow to a film thickness of approximately 30 nm. It is seen from these results that use of a lower growth rate yields a sufficient diffusion length on the terrace. That is, AlGaN of high crystalline performance may be produced from the initial stage by decreasing the amount of AlGaN supplied and by lowering the growth rate, insofar as growth at ambient temperature is concerned.

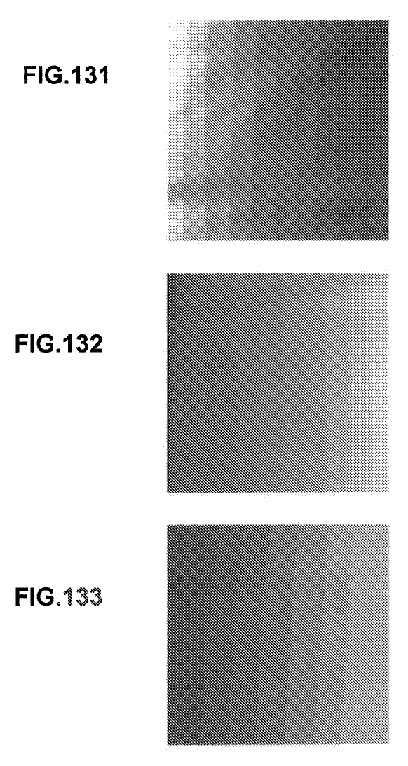

FIGS. 131 to 133 depicts AFM images for cases where AlGaN, grown at ambient temperature, is heat-treated at ambient temperature, 300° C. and at 700° C., respectively. It is seen that, since AlGaN, grown at ambient temperature, keeps a step- and terrace structure, even if heat-treated at 750° C., AlGaN grown at ambient temperature may be used effectively as a buffer layer in the course of the high-temperature growth process.

According to the present invention, described above, a nitride of a group III element, represented by a chemical formula InXGaYA_{1-x-y}N, where 0≦X+Y≦1, is grown at a low temperature on a lattice-matched substrate exhibiting negligible lattice mismatch to the nitride of the group III element, with the use of the PLD method that enables the group III atom to be supplied at a high energy. This suppresses an interfacial reaction between the substrate and the nitride to yield a thin film of the high-quality nitride of the group III element.

In short, with the use of a lattice-matched substrate, having a lattice constant different only a small value from that of the nitride of the group III element to be allowed to grow, it is possible to prevent defects from being generated as well as to suppress the electron mobility from being lowered. Moreover, by allowing the growth of the nitride of the group III element at lower temperature, it is possible to suppress defects and the interfacial reaction to allow the growth of a high-quality buffer layer. The nitride of the group III element is then allowed to grow at high temperature on the so deposited high-quality buffer layer, whereby it is possible to suppress deterioration of the crystalline performance of the nitride of the group III element.

Stated differently, the buffer layer, allowed to grow at lower temperature, transmits the information of a crystal of a high quality and high integrity to the layer of the nitride of the group III element, which is to be grown at high temperature, whereby point defects may be suppressed from being generated at the growth temperature not lower than 500° C. Additionally, the fine grains, present at the time of growth at low temperature, becoming fused together and extinct, thereby appreciably improving the quality of the crystal of the nitride of the group III element. Moreover, the use of InXGaYAl_{1-x-y}N, having a lattice constant close to that of the substrate, as a buffer layer, may further improve the crystal quality.

The present invention is not to be restricted to the embodiments. For example, even with the use of substrate of MgAl₂O₄, LiAlO₂ or NdGaO₃, it is possible to produce a high-quality thin film of a nitride of the group III element, by low-temperature growth followed by high-temperature growth of the nitride of the group III element.

1. A method for generating a GaN film comprising:
a first film-forming step of allowing epitaxial growth of GaN at a temperature not higher than 300° C. on a planarized surface of a ZnO substrate; and
a second film-forming step of allowing epitaxial growth of GaN at a temperature not lower than 550° C. on a film of GaN formed by said first film-forming step.

2. The method for generating a GaN film according to claim 1 wherein, in said first film-forming step, metal Ga and a ZnO substrate are placed in a nitrogen gas atmosphere, and laser light is illuminated on said metal Ga to form a film of GaN on a surface of said ZnO substrate.

3. The method for generating a GaN film according to claim 1 wherein, in said first film-forming step, the initial rate of epitaxial growth is set to 10 nm/hour or less.

4. A method for generating a GaN film comprising:
a first film-forming step of allowing epitaxial growth of InGaN on a planarized surface of a ZnO substrate;
a second film-forming step of allowing epitaxial growth of GaN at a temperature not higher than 320° C. on a film of InGaN formed by said first film-forming step; and
a third film-forming step of allowing epitaxial growth of GaN at a temperature not lower than 550° C. on a film of GaN formed by said second film-forming step.

5. The method for generating a GaN film according to claim 4 wherein, in said second film-forming step, metal Ga and a ZnO substrate are placed in a nitrogen gas atmosphere, and laser light is illuminated on said metal Ga to form a film of GaN on the surface of said ZnO substrate.

6. A semiconductor device including a ZnO substrate, having a planarized surface, and a GaN film, formed on said ZnO substrate; said GaN film having been formed by a first film-forming step of allowing epitaxial growth of GaN at a temperature not higher than 300° C., and a second film-forming step of allowing epitaxial growth of GaN at a temperature not lower than 550° C. on a film of GaN formed by said first film-forming step.

7. The semiconductor device according to claim 6 wherein, in said first film-forming step, metal Ga and a ZnO substrate are placed in a nitrogen gas atmosphere, and laser light is illuminated on said metal Ga to form a film of GaN on the surface of said ZnO substrate.

8. The semiconductor device according to claim 6 wherein, in said first film-forming step, the initial rate of epitaxial growth is set to 10 nm/hour or less.

9. A semiconductor device including a ZnO substrate, having a planarized surface, an InGaN layer formed on said surface of said ZnO substrate, and a GaN film, formed on said InGaN layer; said InGaN film having been formed by a first film-forming step of allowing epitaxial growth of InGaN on the planarized surface of the ZnO substrate; said GaN film having been formed by a second film-forming step of allowing epitaxial growth of GaN at a temperature not higher than 320° C. on a layer of InGaN formed by said first film-forming step, and by a third film-forming step of allowing epitaxial growth of GaN at a temperature not lower than 550° C. on a layer of GaN formed by said second film-forming step.

10. The semiconductor device according to claim 9 wherein, in said second film-forming step, metal Ga and the ZnO substrate are placed in a nitrogen gas atmosphere, and laser light is illuminated on said metal Ga to form a film of GaN on said surface of said ZnO substrate.

11. A GaN crystal comprising:
a first GaN layer generated by epitaxial growth at a temperature not higher than 300° C.; and
a second GaN layer formed on said first GaN layer by epitaxial growth at a temperature not lower than 550° C.

12. The GaN crystal according to claim 11 wherein said first GaN layer has been formed on the planarized surface of a ZnO substrate.

13. An InGaN/GaN crystal comprising:
an InGaN layer generated by epitaxial growth;
a first GaN layer generated by epitaxial growth at a temperature not higher than 320° C.; and
a second GaN layer formed on said first GaN layer by epitaxial growth at a temperature not lower than 550° C.

14. The GaN crystal according to claim 13 wherein said first InGaN layer has been formed on a planarized surface of a ZnO substrate.

15. A method for generating a thin film of a nitride of a group III element, comprising:
a first film-forming step of allowing epitaxial growth of a nitride of a group III element at a temperature not higher than 300° C. on a planarized surface of a substrate lattice-matched to said nitride of the group III element; and
a second film-forming step of allowing epitaxial growth of said nitride of the group III element at a temperature not lower than 550° C. on said nitride of the group III element formed by said first film-forming step.

16. The method for generating a thin film of a nitride of a group III element according to claim 15 wherein, in said first film-forming step, a group III metal and said substrate are placed in a nitrogen gas atmosphere, and laser light is illuminated on said group III metal to form a film of the group III metal on the surface of said lattice-matched substrate.

17. The method for generating a thin film of a nitride of a group III element according to claim 15 wherein said nitride of the group III element is a compound shown by InXGaYAl_{1-x-y}N, where 0≦X≦1, 0≦Y≦1 and X0≦X+Y≦1.

18. The method for generating a thin film according to claim 16 or 17 wherein said group III element is InXGaYAl_{1x-y}, where 0≦X≦1, 0≦Y≦1 and X0≦X+Y≦1.

19. The method for generating a thin film according to any one of claims 15 to 18 wherein said lattice-matched substrate is of a material selected from the group consisting of SiC, Hf, LiGaO₂, (MnZn) Fe₂O₄, MgAl₂O₄, LiAlO₂ and NdGaO₃.

20. The method for generating a thin film according to claim 15 or 16 wherein, if said lattice-matched substrate is formed of LiGaO₂, said nitride of the group III element is allowed to grow on a planarized Metal-face thereof.

21. A semiconductor device comprising:
a substrate with a planarized surface, lattice-matched to a nitride of the group III element, and
a film of said nitride of the group III element, formed on said lattice-matched substrate;
said film of said nitride of the group III element having been formed by a first film-forming step of allowing epitaxial growth of a nitride of a group III element at a temperature not higher than 300° C.; and
a second film-forming step of allowing epitaxial growth of said nitride of the group III element at a temperature not lower than 550° C. on a film of said nitride of the group III element formed by said first film-forming step.

22. The semiconductor device according to claim 21 wherein, in said first film-forming step, a group III metal and a lattice-matched substrate are placed in a nitrogen gas atmosphere, and laser light is illuminated on said group III metal to form a film of said nitride of said group III metal on a surface of said lattice-matched substrate.

23. A crystal of a group III element comprising:
a first layer of a nitride of a group III element, generated by epitaxial growth at a temperature not higher than 300° C.; and
a second layer of a nitride of a group III element, formed on said first layer of the nitride of the group III element by epitaxial growth at a temperature not lower than 550° C.

24. The crystal of a group III element according to claim 23 wherein said first layer of the nitride of the group III element has been formed on a planarized surface of a lattice-matched substrate.
